(19) United States
(12) Patent Application Publication
(10) Pub. No.: US 2026/0040711 A1
(43) Pub. Date: Feb. 5, 2026

(54) SEMICONDUCTOR DIE PACKAGES AND METHODS OF FORMATION

(71) Applicant: Taiwan Semiconductor Manufacturing Company, Ltd., Hsinchu (TW)

(72) Inventors: Hung Yu WANG, Keelung City (TW); Kai-Chun HSU, Yonghe City (TW); Cheng-Ying HO, Minxiong Township (TW); Wen-De WANG, Minsyong Township (TW); Yuh Ruey HUANG, Hsinchu County (TW); Cheng-Yu HSIEH, Tainan City (TW); Jen-Cheng LIU, Hsin-Chu City (TW)

(21) Appl. No.: 18/791,828

(22) Filed: Aug. 1, 2024

(51) Int. Cl. H01L 27/146; H01L 21/768; H01L 23/00; H01L 23/48; H01L 23/522; H01L 25/16; H01L 27/12; H01L 29/94

(52) U.S. Cl. CPC H10F 39/809; H01L 21/76877; H01L 23/5223; H01L 24/08; H01L 24/80; H01L 25/167; H10D 87/00; H01L 23/481; H01L 24/09; H01L 2224/08145; H01L 2224/09181; H01L 2224/80895; H01L 2224/80896; H10D 1/665; H10D 1/68; H10F 39/18

(57) ABSTRACT

An image sensor device includes capacitor structures in multiple semiconductor dies of the image sensor device. The capacitor structures may be located on a frontside of the sensor die, on a frontside of an application specific integrated circuit (ASIC) die directly bonded to the sensor die, and on a backside of the ASIC die, among other examples. Including capacitor structures on the frontside and on the backside of the ASIC die enables more efficient use of the die area of the ASIC die for integration of the capacitor structures, which may enable the density of capacitor structures in the image sensor device to be increased without sacrificing area on the sensor die for the photodiodes of the pixel sensors.

### BACKGROUND

Various semiconductor device packing techniques may be used to incorporate one or more semiconductor dies into a semiconductor die package. In some cases, semiconductor dies may be horizontally interconnected through an interposer. Additionally and/or alternatively, semiconductor dies may be arranged vertically in a semiconductor die package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor die package described herein.

FIGS. 2A and 2B are diagrams of example capacitor structures described herein.

FIGS. 3A-3E are diagrams of an example implementation of forming a semiconductor die (or a portion thereof) described herein.

FIGS. 4A-4D are diagrams of an example implementation of forming a semiconductor die (or a portion thereof) described herein.

FIGS. 5A-5D are diagrams of an example implementation of forming a semiconductor die package (or a portion thereof) described herein.

FIGS. 6A and 6B are diagrams of an example implementation of forming a semiconductor die package (or a portion thereof) described herein.

FIGS. 7A-7K are diagrams of example implementations of a semiconductor die package described herein.

FIG. 8 is a flowchart of an example process associated with forming a semiconductor die package described herein.

FIG. 9 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A complementary metal oxide semiconductor (CMOS) image sensor device may include a plurality of semiconductor dies that are bonded together in a vertical stack. An image sensor die in the vertical stack may include a plurality of pixel sensors arranged in a pixel sensor array. A pixel sensor of the pixel sensor array may include a photodiode configured to convert photons of incident light to a photocurrent. The magnitude of the photocurrent is based at least in part on the intensity of the incident light. Accordingly, if the pixel sensors in the pixel sensor array are capable of sensing incident light across a broad range of intensity, a high range of brightness and contrast may be achieved in images and/or video generated by the CMOS image sensor device.

In some cases, a pixel sensor may be limited in the number of photons of incident light that can be absorbed before reaching saturation of the pixel sensor. “Saturation” refers to a level of photon absorption past which additional photons of light cannot be absorbed by the pixel sensor. Saturation of the pixel sensor results in limited dynamic range for the pixel sensor because additional brightness and color information cannot be obtained from further absorption of photons.

The amount of photocurrent charge that can be stored in a pixel sensor before reaching saturation may be referred to as the full well capacity (FWC) of the pixel sensor. The full well capacity of the pixel sensor may be based at least in part on the size (e.g., the depth, the width, the volume) of the photodiode of the pixel sensor and/or the shape of the photodiode, among other examples. However, while increasing the size of the photodiode may increase the full well capacity of the pixel sensor, doing so may come at the expense of decreasing the density of pixel sensors in the pixel sensor array, which may reduce the resolution of the pixel sensor array.

In some implementations described herein, an image sensor device (e.g., a complementary metal-oxide-semiconductor (CMOS) image sensor device) includes capacitor structures in multiple semiconductor dies of the image sensor device. The capacitor structures may be configured to store charge associated with a photocurrent that is generated by pixel sensors in a pixel sensor array of a sensor die of the image sensor device. Capacitor structures may be located on a frontside of the sensor die, on a frontside of an application specific integrated circuit (ASIC) die directly bonded to the sensor die, and on a backside of the ASIC die, among other examples. The capacitor structures included on the backside of the ASIC die may be included in a backside of a semiconductor substrate of the ASIC die, and/or may be included in an interconnect layer (e.g., a back end of line (BEOL) region or backend region) vertically adjacent to the semiconductor substrate. Including capacitor structures on the frontside and on the backside of the ASIC die enables more efficient use of the die area of the ASIC die for integration of the capacitor structures, which may enable the density of capacitor structures in the image sensor device to be increased without sacrificing area on the sensor die for the photodiodes of the pixel sensors.

The photocurrents generated by the pixel sensors of the pixel sensor array may be transferred to the capacitor structures located throughout the semiconductor dies of the image sensor device, which enables the pixel sensors to generate more charge for the photocurrents than if the photocurrents were wholly stored in the photodiodes and/or in floating diffusion nodes of the pixel sensors. Thus, the capacitor structures may increase the full well capacity of the pixel sensors. The increased full well capacity of the pixel sensors may enable a higher range of brightness and/or contrast to be achieved in images and/or video generated by the pixel sensor array.

Additionally and/or alternatively, the increased full well capacity of the pixel sensor may enable global shutter functionality to be implemented in the image sensor device. Global shutter is an image sensor exposure technique in which all pixel sensors of a pixel sensor array are simultaneously exposed to incident light, as opposed to sequentially exposing rows of pixel sensors (which is referred to as rolling shutter). Rolling shutter may produce incomplete images and/or distortions when capturing fast-moving objects using such progressive exposure, which may result in deformed images due to the output time difference. The increased full well capacity provided by the capacitor structures in the image sensor device enables the pixel sensors in the pixel sensor array of the image sensor device to simultaneously accumulate charge from incident light during a global shutter exposure, which may improve image quality for fast-moving objects, may reduce image blur, and may increase image quality.

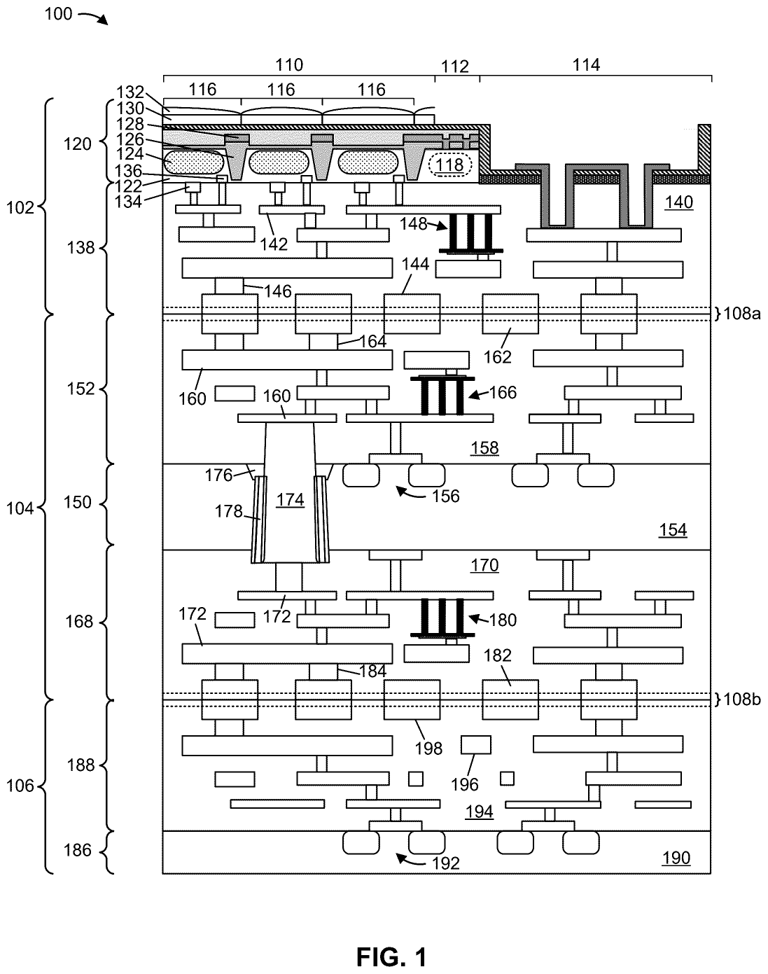

FIG. 1 is a diagram of an example semiconductor die package 100 described herein. FIG. 1 illustrates a cross-section view of the semiconductor die package 100. As shown in FIG. 1, the semiconductor die package 100 includes a plurality of semiconductor dies, including a semiconductor die 102, a semiconductor die 104, and a semiconductor die 106, among other examples. Other quantities of semiconductor dies for the semiconductor die package 100 are within the scope of the present disclosure.

The semiconductor dies 102-106 may be vertically stacked or vertically arranged in the semiconductor die package 100. For example, the semiconductor die 102 and the semiconductor die 104 may be bonded at a bonding interface 108a such that the semiconductor dies 102 and 104 are stacked and vertically arranged in the semiconductor die package 100. As another example, the semiconductor die 104 and the semiconductor die 106 may be bonded at a bonding interface 108b such that the semiconductor dies 104 and 106 are stacked and vertically arranged in the semiconductor die package 100. The bond between the semiconductor dies 102 and 104, and the bond between the semiconductor dies 104 and 106, may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 108a between the semiconductor dies 102 and 104. A bonding tool may be used to perform a bonding operation to bond the semiconductor dies 104 and 106 by forming metal-to-metal bonds and/or dielectric-to-dielectric bonds at the bonding interface 108b between the semiconductor dies 104 and 106.

The semiconductor die 102 may be an image sensor die of the semiconductor die package 100. The semiconductor die package 100 may be configured to generate images and/or video based on sensing performed by the semiconductor die 102. Thus, the semiconductor die package 100 may be an image sensor device such as a CMOS image sensor (CIS). In particular, the semiconductor die package 100 may be a three-dimensional (3D) CIS because of the vertical arrangement of the semiconductor dies 102-106.

As shown in FIG. 1, the semiconductor die 102 may include a pixel sensor array 110, a black level correction (BLC) region 112 adjacent to (e.g., horizontally adjacent to) the pixel sensor array 110, and a bonding pad region 114 adjacent to (e.g., horizontally adjacent to) the BLC region 112, among other examples. The pixel sensor array 110 includes a plurality of pixel sensors 116. The pixel sensors 116 may be arranged in a grid or in another type of arrangement, and may be configured to generate photocurrents based on photons of incident light. The BLC region 112 may include a region 118 in the device layer 120 that is shielded from incident light by a metal shielding layer. The metal shielding layer may be included as a light-blocking layer to prevent incident light from entering the region 118. The region 118 is thus a sensing region that is kept “dark” so that dark current measurements may be performed in the BLC region 112. A dark current measurement may be performed to measure the amount of charge (dark current) in the device layer 120 that is generated from sources other than incident light (e.g., from thermal energy in the device layer 120) so that the dark current measurement may be used for black level correction (or black level calibration) for the pixel sensor array 110. The bonding pad region 114 may include a bonding pad structure that enables an external electrical connection to be formed to the semiconductor die package 100.

The device layer 120 includes a substrate layer 122. The substrate layer 122 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, or another type of semiconductor material.

Photodiodes 124 of the pixel sensors 116 are included in the substrate layer 122 of the semiconductor die 102. The photodiodes 124 may each include one or more doped regions of substrate layer 122. The substrate layer 122 may be doped with a plurality of types of ions to form a p-n junction or a PIN junction (e.g., a junction between a p-type portion, an intrinsic (or undoped) type portion, and an n-type portion) corresponding to a photodiode 124. For example, the substrate layer 122 may be doped with an n-type dopant to form a first portion (e.g., an n-type portion) of a photodiode 124 and a p-type dopant to form a second portion (e.g., a p-type portion) of the photodiode 124. A photodiode 124 may be configured to absorb photons of incident light. The absorption of photons causes the photodiode 124 to accumulate a charge (a photocurrent) due to the photoelectric effect. Here, photons bombard the photodiode 124, which causes emission of electrons of the photodiode 124. The emission of electrons causes the formation of electron-hole pairs, where the electrons migrate toward the cathode of the photodiode 124 and the holes migrate toward the anode, which produces the photocurrent.

The photodiodes 124 may be electrically isolated and/or optically isolated from one another by one or more isolation structures in the substrate layer 122. For example, a deep trench isolation (DTI) structure 126 may extend into the substrate layer 122 from a backside of the substrate layer 122. The DTI structure 126 may include elongated structures that include a one or more dielectric layers, one or more metal layers, and/or another arrangement of layers and/or materials. The DTI structure 126 may laterally surround the photodiodes 124 of the pixel sensors 116 in the substrate layer 122.

A grid structure 128 may be included above the backside of the substrate layer 122. Sections of the grid structure 128 may be located over the DTI structure 126 and may be formed around the perimeter of the photodiodes 124 of the pixel sensors 116. Openings in the grid structure 128 are included above the photodiodes 124 to enable incident light to pass through the grid structure 128 and to the photodiodes 124. In some implementations, the grid structure 128 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples. In some implementations, the grid structure 128 may be formed of a dielectric material such as a silicon oxide (SiOₓ) a silicon nitride (SiₓN_{y}), silicon carbide (SiC), silicon oxynitride (SiON), and/or another suitable dielectric material. In some implementations, the grid structure 128 may include a multiple-layer structure that includes a dielectric layer and a metal layer on the dielectric layer, or another combination of dielectric layers and metal layers.

Color filter regions 130 of the pixel sensors 116 be included in the openings in the grid structure 128. The color filter regions 130 may be included above the photodiodes 124 of the pixel sensors 116. The color filter regions 130 may be included above the photodiodes 124. Each color filter region 130 may be configured to filter incident light to allow a particular wavelength of the incident light to pass to a photodiode 124. For example, a color filter region 130 may filter incident light to allow red light to pass through the color filter region 130 to an associated photodiode 124. As another example, a color filter region 130 may filter incident light to allow green light to pass through the color filter region 130 to an associated photodiode 124. As another example, a color filter region 130 may filter incident light to allow blue light to pass through the color filter region 130 to an associated photodiode 124. In some implementations, a color filter region 130 may be non-discriminating or non-filtering, which may define a white pixel sensor. A non-discriminating or non-filtering color filter region 130 may include a material that permits all wavelengths of light to pass into the associated photodiode 124 (e.g., for purposes of determining overall brightness to increase light sensitivity for the image sensor). In some implementations, a color filter region 130 may be a near infrared (NIR) bandpass color filter region 130, which may define an NIR pixel sensor. An NIR bandpass color filter region 130 may include a material that permits the portion of incident light in an NIR wavelength range to pass to an associated photodiode 124 while blocking visible light from passing.

Micro-lenses 132 may be included over and/or on the color filter regions 130. The micro-lenses 132 may include a respective micro-lens for each of the pixel sensors 116. A micro-lens may be formed to focus incident light toward a photodiode 124 of an associated pixel sensor 116.

Transfer gates 134 of the pixel sensors 116 are included on the frontside of the substrate layer 122. The transfer gates 134 are configured to selectively control the flow of photocurrents from the photodiodes 124 to floating diffusion nodes 136 of the pixel sensors 116. The floating diffusion nodes 136 are included in the substrate layer 122 and are configured to temporarily store photocurrents generated by the photodiodes 124. A transfer gate 134 may selectively control the flow of a photocurrent from a photodiode 124 of a pixel sensor 116 to a floating diffusion node 136 of the pixel sensor 116 by selectively controlling a leakage path (e.g., a buried channel) between the photodiode 124 and the floating diffusion node 136 in the substrate layer 122. When a gate voltage is applied to the transfer gate 134, the leakage path may be formed in the substrate layer 122, thereby enabling a photocurrent to flow from the photodiode 124 to the floating diffusion node 136. When the gate voltage is removed, the leakage path is closed, thereby preventing the photocurrent from floating from the photodiode 124 to the floating diffusion node 136.

The semiconductor die 102 may include an interconnect layer 138 vertically adjacent to the device layer 120. The interconnect layer 138 may include a dielectric region 140 that includes one or more dielectric layers. The dielectric layer may include backend dielectric layers (e.g., interlayer dielectric (ILD) layers, intermetal dielectric (IMD) layers) and etch stop layers (ESLs) that are arranged in a direction that is approximately orthogonal to the substrate layer 122. The dielectric region 140 may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 138 may further include a plurality of conductive structures 142 (e.g., electrically conductive structures) in the dielectric region 140. The conductive structures 142 are electrically coupled and/or physically coupled to the transfer gates 134, the floating diffusion nodes 136, and/or other structures in the device layer 120. Moreover, the conductive structures 142 may be electrically interconnected together in the interconnect layer 138. The conductive structures 142 correspond to circuit routing that enables signals and/or power to be provided to and/or from the pixel sensors 116 and/or other integrated circuit devices in the device layer 120. The conductive structures 142 may include a combination of conductive structures that extend primarily horizontally in the interconnect layer 138 (e.g., trenches, conductive lines) and that are interconnected by interconnect structures (e.g., vias) that extend primarily vertically in the interconnect layer 138. The conductive structures 142 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 138 may be arranged in a vertical manner to facilitate electrical signals and/or power to be routed between the device layer 120 and the semiconductor die 104, between integrated circuit devices in the device layer 120 through the interconnect layer 138, and/or between the integrated circuit devices in the device layer 120 and integrated circuit devices in the semiconductor dies 104 and/or 106. The conductive structures 142 may be arranged in alternating layers of metallization layers (referred to as “M”-layers) and via layers (referred to as “V”-layers). Each metallization layer may include one or more conductive structures laterally arranged in the interconnect layer 138, and each via layer may include one or more interconnect structures that interconnect the metallization layers in the interconnect layer 138. As an example, a metal-0 (M0) layer may be located at the bottom of the interconnect layer 138 and may be coupled to the integrated circuit devices (e.g., the transfer gates 134, the floating diffusion nodes 136) in the device layer 120, a via-0 (V0) layer may be located above and coupled to the M0 layer in the interconnect layer 138, a metal-1 (M1) layer may be located above and coupled to the V0 layer in the interconnect layer 138, a via-1 (V1) layer may be located above and coupled to the M1 layer in the interconnect layer 138, a metal-2 (M2) layer may be located above and electrically coupled to the V1 layer in the interconnect layer 138, and so on. In some implementations, the interconnect layer 138 includes nine (9) stacked metallization layers (e.g., M0-M8). In other implementations, the contact layer (referred to as “CO”-layer) may be located at the bottom of the interconnect layer 138 and may be directly coupled to the integrated circuit devices (e.g., with the transfer gates 134, with the floating diffusion nodes 136) in the device layer 120, a metal-1 (M1) layer may be located above and coupled to the CO layer in the interconnect layer 138, and so on. In some implementations, the interconnect layer 138 includes another quantity of stacked metallization layers.

At the bonding interface 108a between the semiconductor dies 102 and 104, the interconnect layer 138 may include a plurality of bonding pads 144. The bonding pads 144 may be electrically coupled to the conductive structures 142 in the interconnect layer 138 by bonding vias 146 and/or other types of conductive structures. The bonding pads 144 and the bonding vias 146 may each include tungsten (W), cobalt (Co), ruthenium (Ru), titanium (Ti), aluminum (Al), copper (Cu), gold (Au), and/or a combination thereof, among other examples of electrically conductive metals.

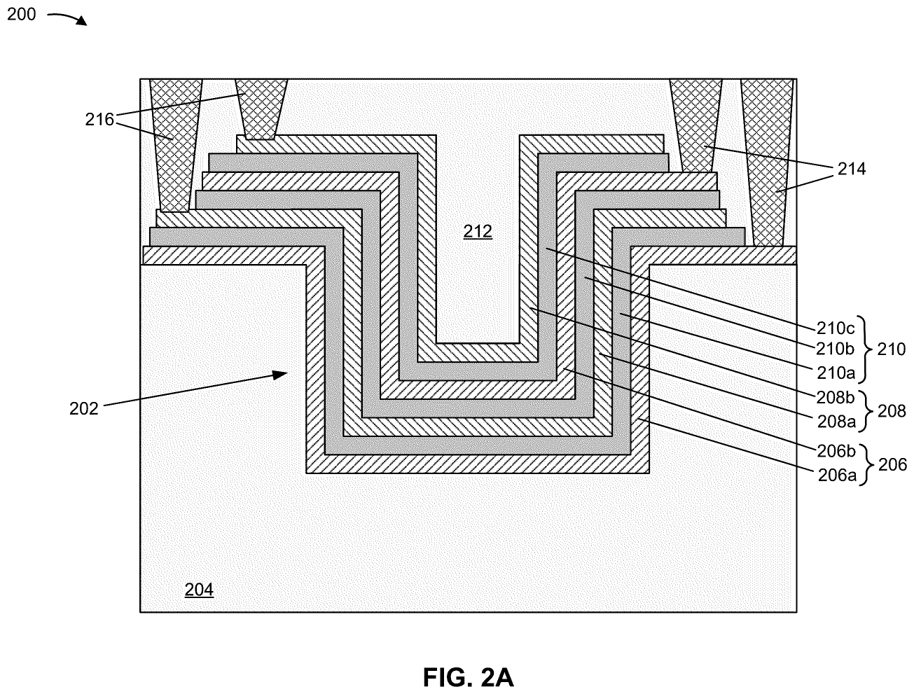

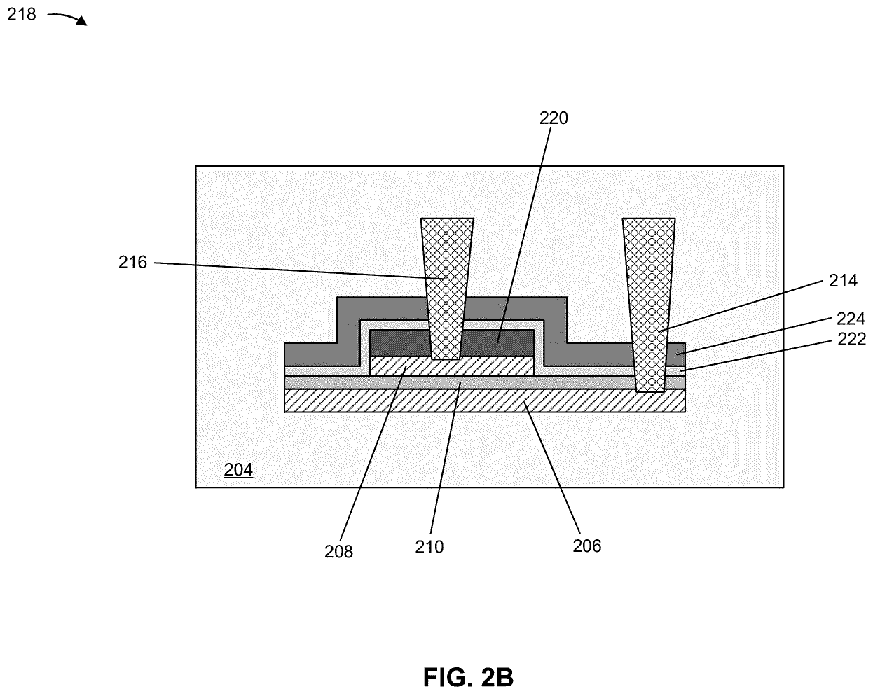

As further shown in FIG. 1, one or more capacitor structures 148 may be included in the interconnect layer 138 and may be electrically coupled to one or more conductive structures 142 in the interconnect layer 138. The one or more capacitor structures 148 may be electrically coupled to one or more pixel sensors 116 through the conductive structures 142, and may be configured to store overflow photocurrents from the floating diffusion nodes 136 of the pixel sensors 116 to facilitate increased full well capacity. This may enable a higher dynamic range to be achieved for the pixel sensors 116 and/or may enable global shutter functionality to be implemented in the semiconductor die package 100. Example structural implementations for the capacitor structure(s) 148 are illustrated and described in connection with FIGS. 2A and 2B.

The semiconductor die 104 may be an ASIC die or a system on chip (SoC) die of the semiconductor die package 100. The semiconductor die 104 may include the control circuitry associated with the pixel sensors 116 of the semiconductor die 102. The semiconductor die 104 may include a device layer 150 and an interconnect layer 152 vertically adjacent to the device layer 150. The device layer 150 may include a substrate layer 154 and one or more integrated circuit devices 156 in the substrate layer 154. The substrate layer 154 may include a silicon (Si) substrate and/or another type of semiconductor substrate. The integrated circuit devices 156 may correspond to the control circuitry associated with the pixel sensors 116 of the semiconductor die 102. For example, the integrated circuit devices 156 may include source follower gates for the pixel sensors 116, may include row select gates for the pixel sensors 116, may include overflow gates for the pixel sensors 116, and/or may include other control circuitry devices for the pixel sensors 116. The integrated circuit devices 156 may be included in a first side (e.g., a frontside) of the substrate layer 154, and may each include planar transistors, fin field effect transistors (finFETs), nanostructure (e.g., nanosheet transistors, gate all around (GAA) transistors), and/or other types of integrated circuit devices.

The interconnect layer 152 may be located vertically adjacent to the first side (e.g., the frontside) of the substrate layer 154. The interconnect layer 152 may include a similar combination and/or arrangement of structures and/or layers as the interconnect layer 138 of the semiconductor die 102. For example, the interconnect layer 152 may include a dielectric region 158 (similar to the dielectric region 140) and combination of conductive structures 160 (similar to the conductive structures 142) in the dielectric region 158. Moreover, the interconnect layer 152 may include bonding pads 162 that are electrically coupled to one or more of the conductive structures 160 by bonding vias 164. These layers and/or structures may have a reversed vertical arrangement relative to the semiconductor die 102, which enables the semiconductor die 102 and the semiconductor die 104 to be bonded at the bonding interface 108a such that the interconnect layer 138 and the interconnect layer 152 are facing each other and bonded together.

At the bonding interface 108a, the bonding pads 144 of the semiconductor die 102 and bonding pads 162 of the semiconductor die 104 are directly bonded by metal-to-metal bonds. Moreover, the dielectric region 140 of the semiconductor die 102 and the dielectric region 158 of the semiconductor die 104 are directly bonded by dielectric-to-dielectric bonds. One or more of the bonding pads 162 of the semiconductor die 104 may be electrically coupled to the conductive structures 160 by bonding vias 164.

As further shown in FIG. 1, one or more capacitor structures 166 may be included in the interconnect layer 152 above the frontside of the substrate layer 154 of the semiconductor die 104. The one or more capacitor structures 166 may be electrically coupled to one or more conductive structures 160 in the interconnect layer 152. One or more of the capacitor structures 166 may be electrically coupled to one or more pixel sensors 116 through the conductive structures 142, the bonding vias 146, the bonding pads 144, the bonding pads 162, the bonding vias 164, and/or the conductive structures 160. The capacitor structures 166 may be configured to store overflow photocurrents from the floating diffusion nodes 136 of the pixel sensors 116 to facilitate increased full well capacity. This may enable a higher dynamic range to be achieved for the pixel sensors 116 and/or may enable global shutter functionality to be implemented in the semiconductor die package 100. Example structural implementations for the capacitor structure(s) 166 are illustrated and described in connection with FIGS. 2A and 2B.

As further shown in FIG. 1, the semiconductor die 104 may include another interconnect layer 168. The interconnect layer 168 may be located on a second side (e.g., a backside) of the substrate layer 154 such that the interconnect layers 152 and 168 are located on vertically opposing sides of the substrate layer 154 of the semiconductor die 104. The interconnect layer 168 may be configured to route signals and/or power between the semiconductor dies 104 and 106. The interconnect layer 168 may include a similar combination and/or arrangement of structures and/or layers as the interconnect layer 152 of the semiconductor die 104. For example, the interconnect layer 168 may include a dielectric region 170 (similar to the dielectric region 158) and a combination of conductive structures 172 (similar to the conductive structures 160) in the dielectric region 170.

One or more elongated conductive structures 174 may be included in the semiconductor die 104. An elongated conductive structure 174 may extend between the interconnect layers 152 and 168 through the substrate layer 154 of the device layer 150. An elongated conductive structure 174 may include a through substrate via (TSV), a metal pillar, a metal column, and/or another type of vertically elongated conductive structure that physically connects and electrically connects with a conductive structure 160 (e.g., a metal pad) in the interconnect layer 152 at a first end, and that physically connects and electrically connects with a conductive structure 172 (e.g., a metal pad) in the interconnect layer 168. An elongated conductive structure 174 may be referred to as a TSV structure in that the elongated conductive structure 174 extends fully through the substrate layer 154 (e.g., a semiconductor substrate such as a silicon substrate) of the device layer 150, as opposed to extending fully through a dielectric layer or an insulator layer. An elongated conductive structure 174 may further extend through a shallow trench isolation (STI) region 176 that is included in the substrate layer 154 of the device layer 150. An elongated conductive structure 174 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. The STI region 176 may include one or more dielectric materials such as a silicon oxide material (SiOₓ such as SiO₂), a silicon nitride material (SiₓN_{y} such Si₃N₄), and/or another suitable dielectric material.

One or more liners 178 may be included between the sidewalls of the elongated conductive structure 174 and the substrate layer 154. The one or more liners 178 may include adhesion liners, barrier liners, diffusion liners, and/or another type of liners. In some implementations, a liner 178 includes a high-k dielectric liner that includes a high-k dielectric material having a dielectric constant that is greater than approximately 3.9. Examples of such materials include a silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, a liner 178 includes a low-k dielectric liner that includes a low-k dielectric material. Examples of such materials include a silicon oxide (SiOₓ), an undoped silicate glass (USG), a boron-containing silicate glass (BSG), and/or a fluorine-containing silicate glass (FSG), among other examples.

As further shown in FIG. 1, one or more capacitor structures 180 may be included in the interconnect layer 168 above (or below, depending on the orientation of the semiconductor die package 100) the backside of the substrate layer 154 of the semiconductor die 104. The one or more capacitor structures 180 may be electrically coupled to one or more conductive structures 172 in the interconnect layer 168. One or more of the capacitor structures 180 may be electrically coupled to one or more pixel sensors 116 through the conductive structures 142, the bonding vias 146, the bonding pads 144, the bonding pads 162, the bonding vias 164, the conductive structures 160, an elongated conductive structure 174, and/or the conductive structures 172. The capacitor structures 180 may be configured to store overflow photocurrents from the floating diffusion nodes 136 of the pixel sensors 116 to facilitate increased full well capacity. This may enable a higher dynamic range to be achieved for the pixel sensors 116 and/or may enable global shutter functionality to be implemented in the semiconductor die package 100. Example structural implementations for the capacitor structure(s) 180 are illustrated and described in connection with FIGS. 2A and 2B.

In this way, capacitor structures are included in multiple dies of the semiconductor die package 100, and on multiple sides of the substrate layer 154 of the semiconductor die 104. Including capacitor structures on both sides of the substrate layer 154 of the semiconductor die 104 enables a greater quantity of capacitor structures to be included on the semiconductor die 104, which in turn enables capacitor structures to be moved from the semiconductor die 102 to the semiconductor die 104 so that fewer capacitor structures are included on the semiconductor die 102. This enables a greater amount of the die area of the semiconductor die 102 to instead be utilized for the photodiodes 124 and associated structures of the pixel sensors 116, which may enable the density of pixel sensors 116 to be increased in the pixel sensor array 110 while enabling a greater quantity of capacitor structures to be included in the semiconductor die package 100.

The interconnect layer 168 may further include bonding pads 182 and bonding vias 184. The bonding pads 182 enable the semiconductor die 104 to be bonded to the semiconductor die 106 at the bonding interface 108b, and the bonding vias 184 electrically connect one or more of the bonding pads 182 to the conductive structures 172 in the interconnect layer 168.

The semiconductor die 106 may be an image sensor processing (ISP) die of the semiconductor die package 100. The semiconductor die 106 may include the processing circuitry associated with the pixel sensor array 110 that is configured to perform image processing operations for generating images and/or video based on the photocurrents generated by the pixel sensors 116 in the pixel sensor array 110. Additionally and/or alternatively, processing circuitry of the semiconductor die 106 may be configured to perform functions such as compression, storage, file management, and/or other functions associated with the images and/or video.

The semiconductor die 106 may include a device layer 186 and an interconnect layer 188 vertically adjacent to the device layer 186. The device layer 186 may include a substrate layer 190 and one or more integrated circuit devices 192 in the substrate layer 190. The substrate layer 190 may include a silicon (Si) substrate and/or another type of semiconductor substrate. The integrated circuit devices 192 may correspond to the image processing circuitry of the semiconductor die 106 and may include transistors, capacitors, resistors, and/or other integrated circuit devices.

The interconnect layer 188 may be located vertically adjacent to the frontside of the substrate layer 190. The interconnect layer 188 may include a similar combination and/or arrangement of structures and/or layers as the interconnect layer 168 of the semiconductor die 104. For example, the interconnect layer 188 may include a dielectric region 194 (similar to the dielectric region 170) and combination of conductive structures 196 (similar to the conductive structures 172) in the dielectric region 194. Moreover, the interconnect layer 168 may include bonding pads 198 that are electrically coupled to one or more of the conductive structures 196. These layers and/or structures may have a reversed vertical arrangement relative to the interconnect layer 168, which enables the semiconductor die 104 and the semiconductor die 106 to be bonded at the bonding interface 108b such that the interconnect layer 168 and the interconnect layer 188 are facing each other and bonded together.

At the bonding interface 108b, the bonding pads 182 of the semiconductor die 104 and bonding pads 198 of the semiconductor die 106 are directly bonded by metal-to-metal bonds. Moreover, the dielectric region 170 of the semiconductor die 104 and the dielectric region 194 of the semiconductor die 106 are directly bonded by dielectric-to-dielectric bonds.

As indicated above, FIG. 1 is provided as an example. Other examples may differ from what is described with regard to FIG. 1.

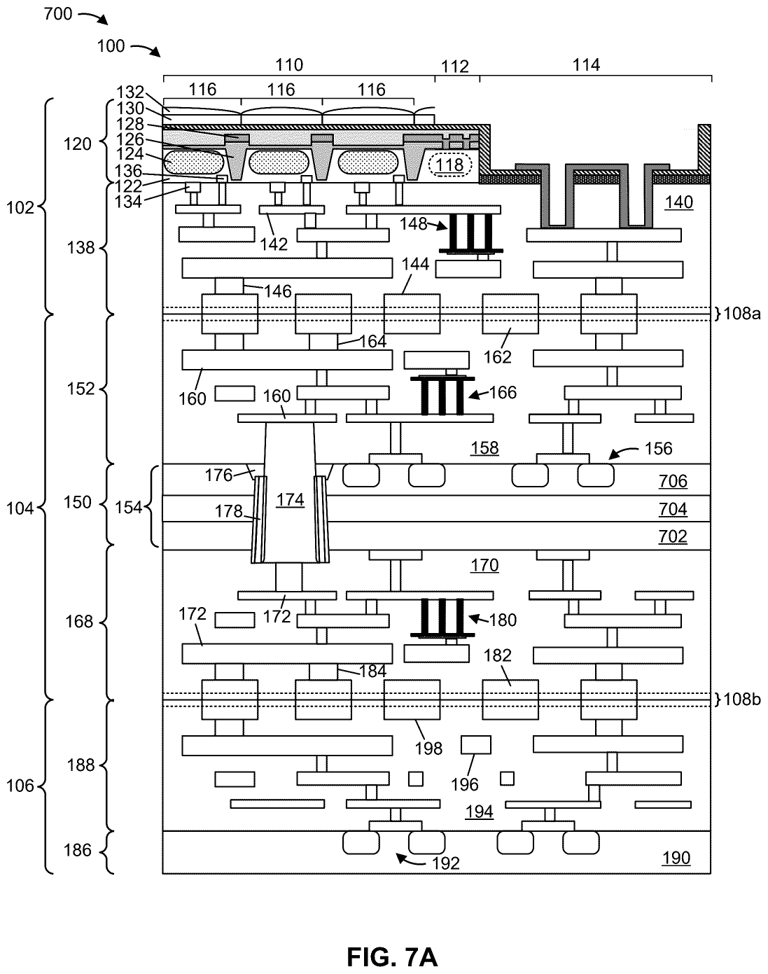

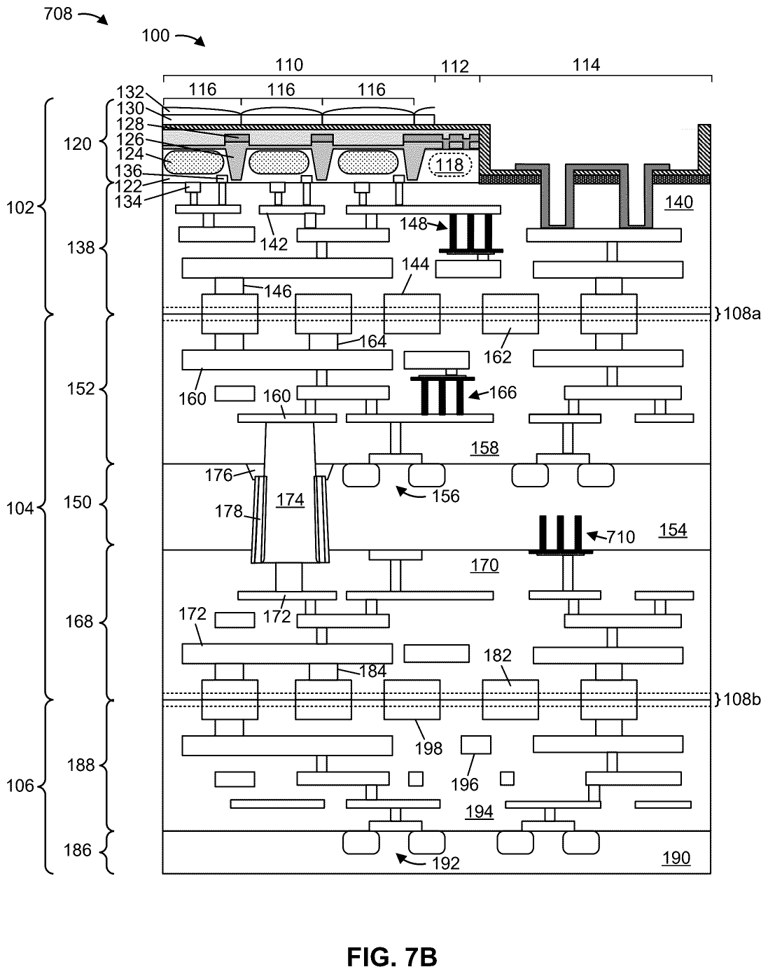

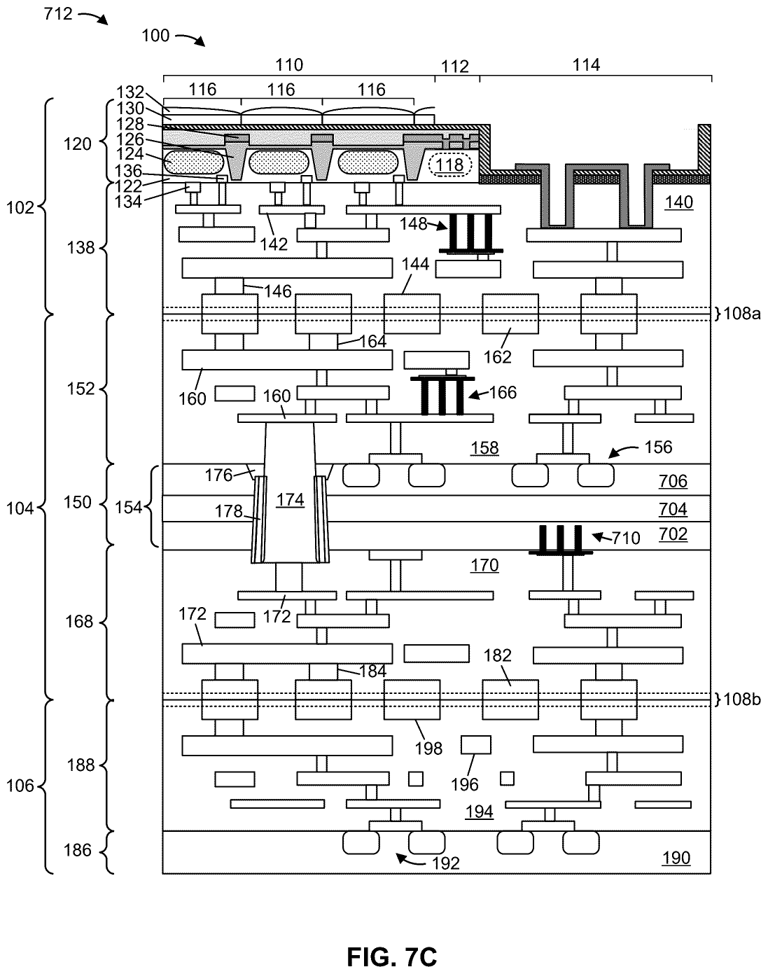

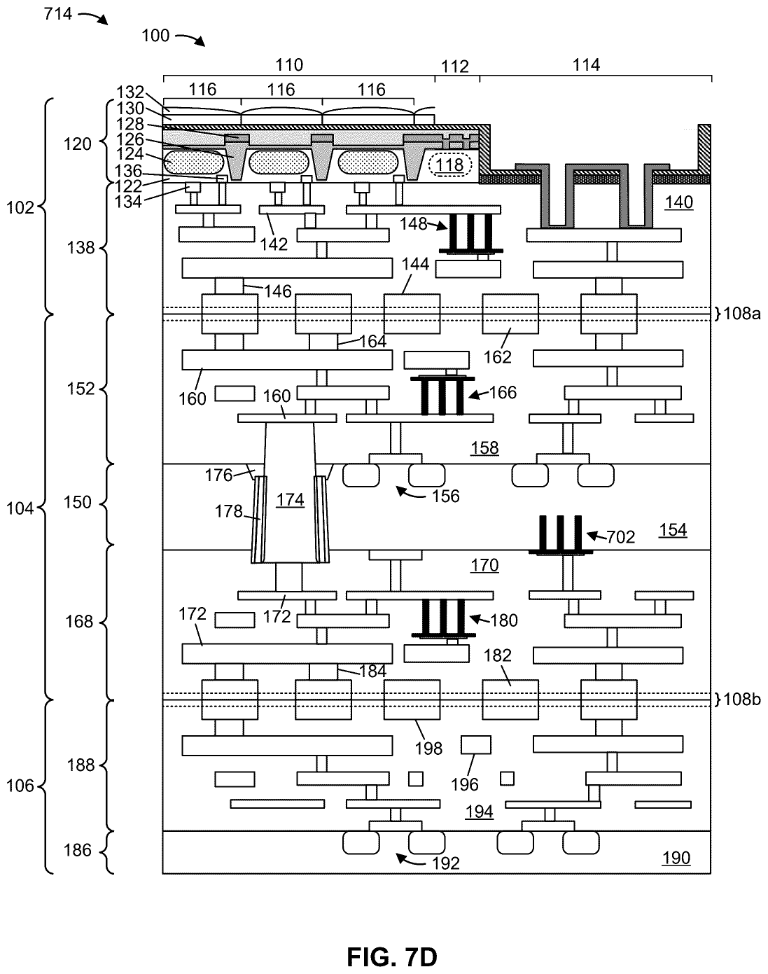

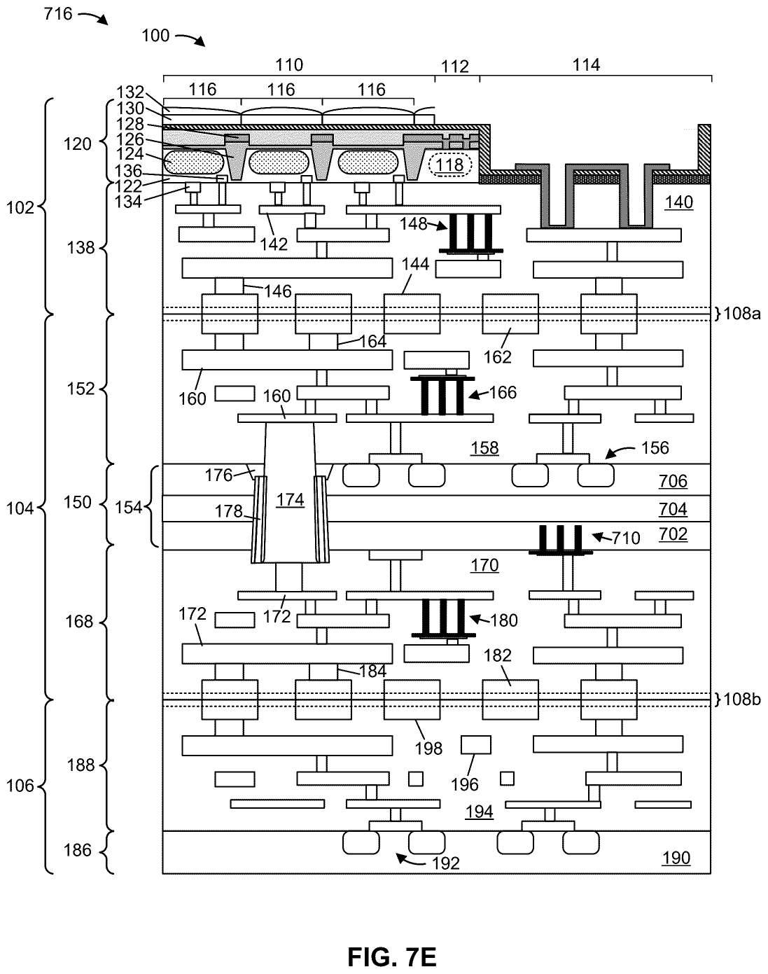

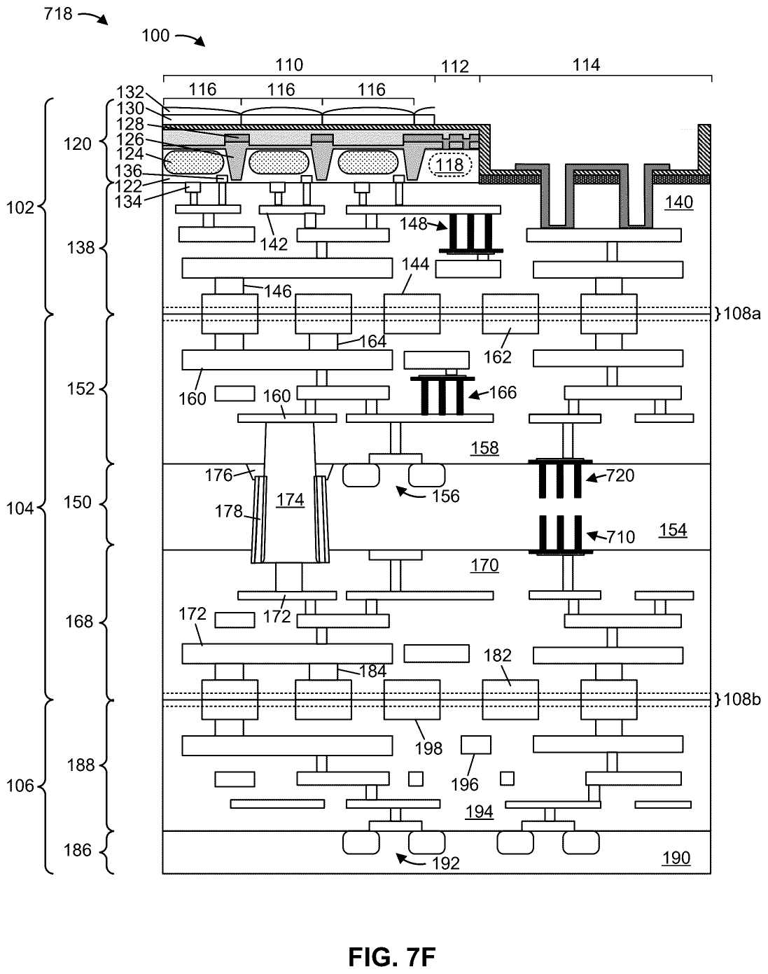

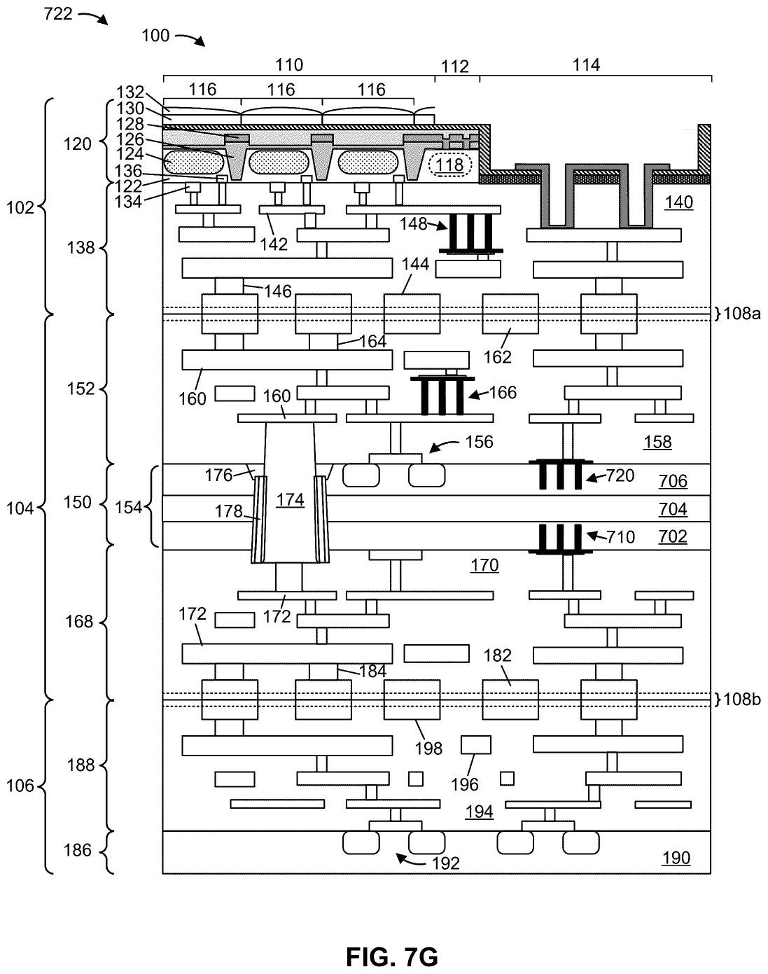

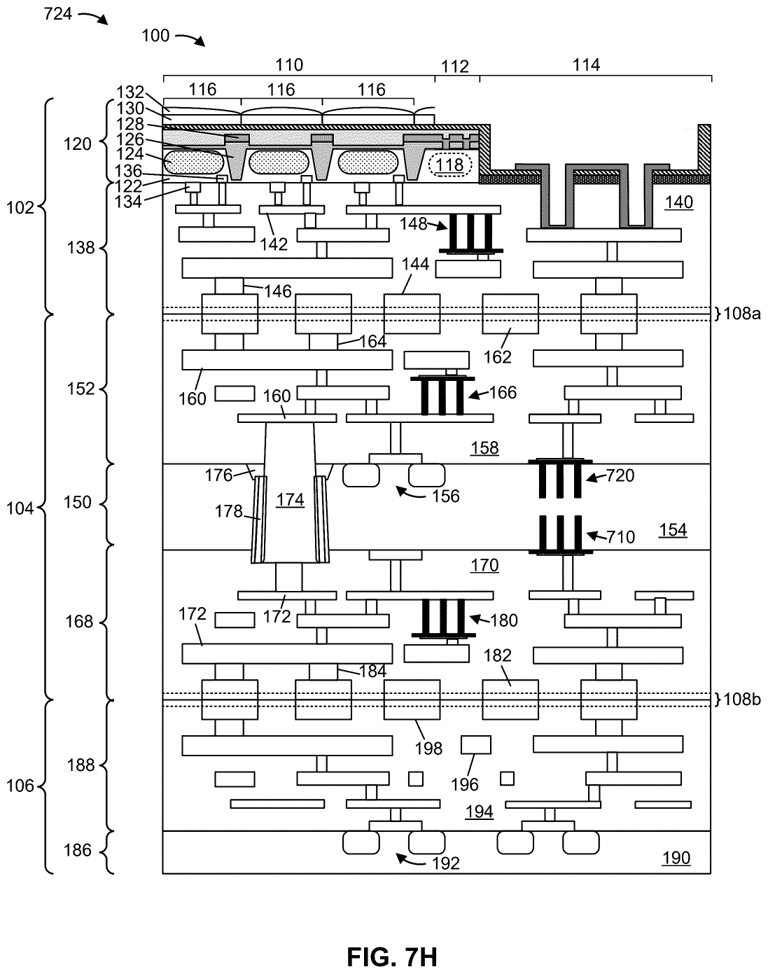

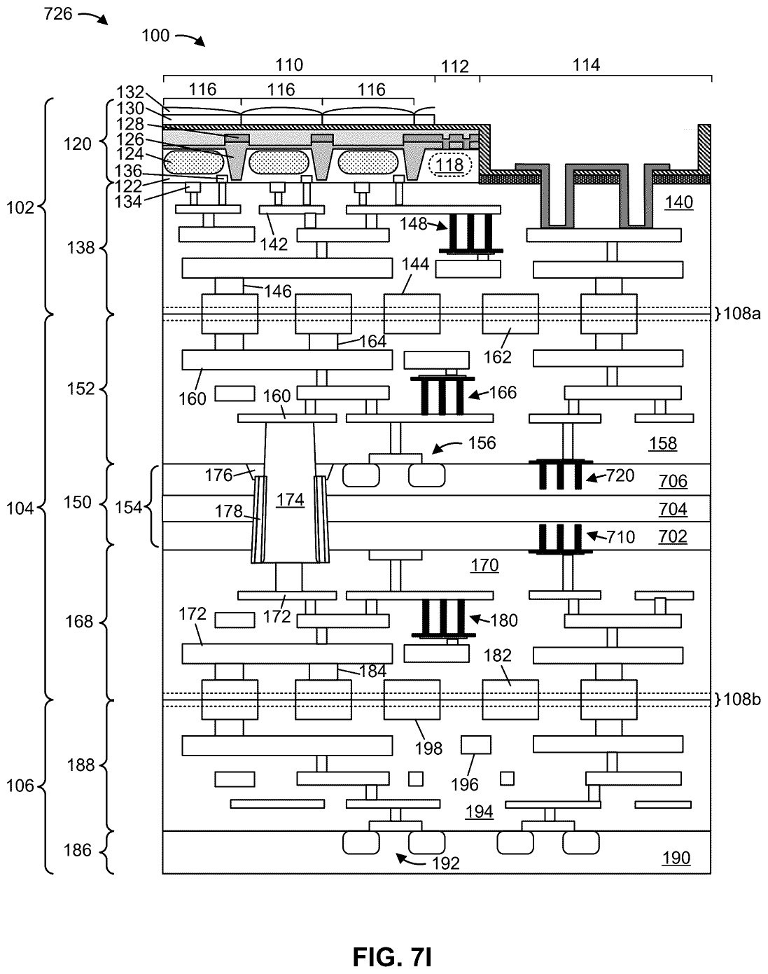

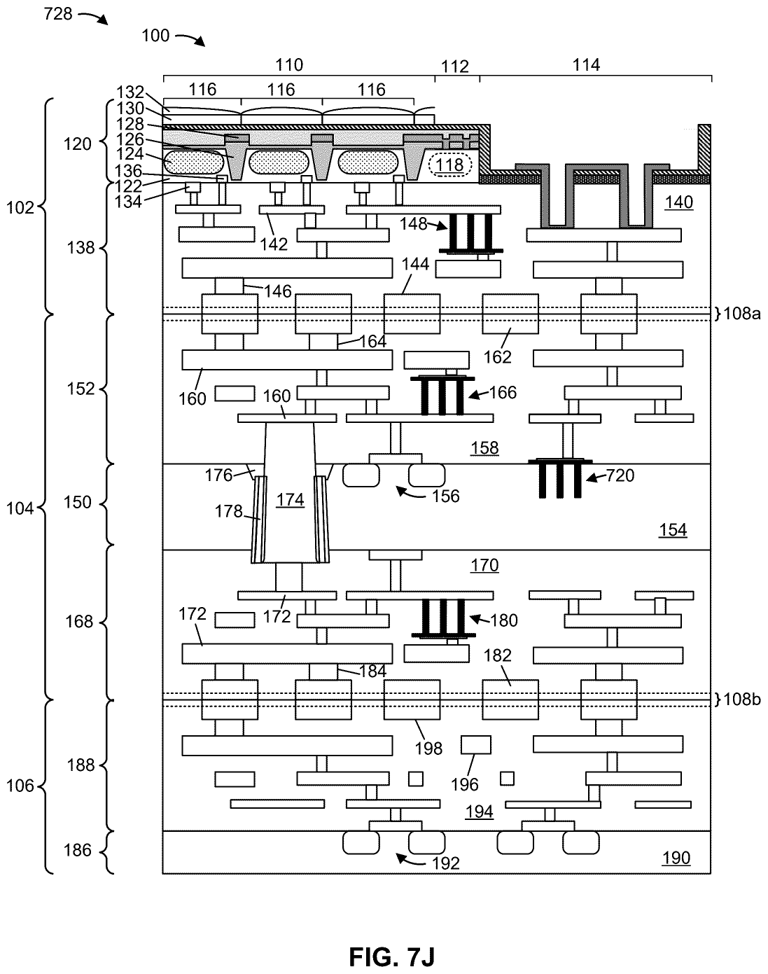

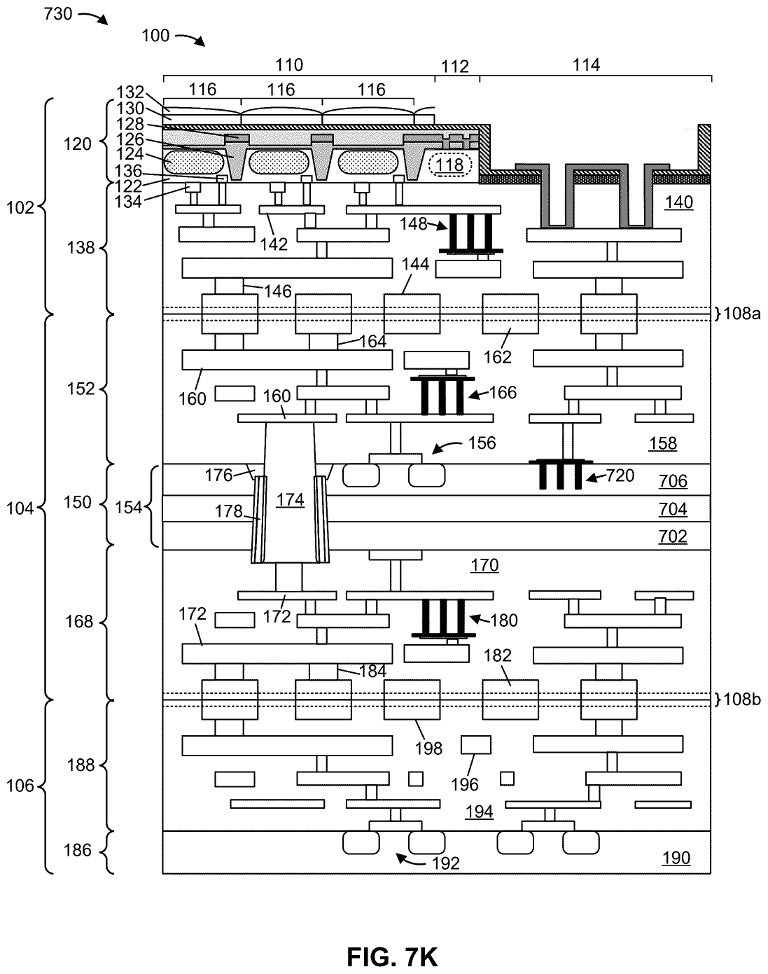

FIGS. 2A and 2B are diagrams of example capacitor structures described herein. One or more of the capacitor structures 148, 166, and/or 180 described in connection with FIG. 1 may be implemented as one or more of the example capacitor structures illustrated in FIGS. 2A and/or 2B. Additionally and/or alternatively, one or more other capacitor structures described herein, such as a capacitor structure 710 and/or a capacitor structure 710 illustrated and described in connection with FIGS. 7A-7K may be implemented as one or more of the example capacitor structures illustrated in FIGS. 2A and/or 2B.

As shown in FIG. 2A, an example the capacitor structure 200 extends into a trench 202 that is formed in a layer 204. Thus, the capacitor structure 200 may be referred to as a trench capacitor structure. In some implementations, the layer 204 is a dielectric layer and may correspond to the dielectric region 140, the dielectric region 158, and/or the dielectric region 170, among other examples. In some implementations, the layer 204 is a semiconductor layer and may correspond to the substrate layer 154 of the semiconductor die 104.

In some implementations, the trench 202 may have a high aspect ratio, which is a ratio of the vertical depth to the lateral width of the trench 202. In these implementations, the capacitor structure 200 may be referred to as a deep trench capacitor (DTC) structure. In some implementations, the aspect ratio of the trench 202 may be approximately 10:1 or greater. In some implementations, the trench 202 may have an aspect ratio that is included in the range of approximately 20:1 to approximately 50:1. However, other values and ranges are within the scope of the present disclosure.

As further shown in FIG. 2, the capacitor structure 200 may include one or more first electrode layers 206 (e.g., bottom electrode layers or capacitor bottom metal (CBM) layers of the capacitor structure 200), one or more second electrode layers 208 (e.g., top electrode layers or capacitor top metal (CTM) layers of the capacitor structure 200), and one or more insulator layers 210. The first electrode layers 206, the second electrode layers 208, and the insulator layers 210 are arranged in a metal-insulator-metal (MIM) stack in the capacitor structure 200. In some implementations, the MIM stack includes a repeating arrangement of a first electrode layer 206, an insulator layer 210 on the first electrode layer 206, and a second electrode layer 208 on the insulator layer 210. For example, a first electrode layer 206a may be located on the sidewalls and on the bottom of the trench 202, an insulator layer 210a may be located on the first electrode layer 206a, a second electrode layer 208a may be located on the insulator layer 210a, another insulator layer 210b may be located on the second electrode layer 208a, another first electrode layer 206b may be located on the insulator layer 210b, another insulator layer 210c may be located on the first electrode layer 206b, and another second electrode layer 208b may be located on the insulator layer 210c. The quantity of first electrode layers 206, the quantity of second electrode layers 208, and the quantity of insulator layers 210 illustrated in FIG. 2A is an example, and other quantities are within the scope of the present disclosure.

The first electrode layers 206, the second electrode layers 208, and the insulator layers 210 may each include conformal layers that conform to the profile of the trench 202. In other words, first electrode layers 206, the second electrode layers 208, and the insulator layers 210 may each extend along the sidewalls of the trench 202, and along the bottom surface of the trench 202. The remaining area in the trench 202 may be filled in with a dielectric layer 212.

The first electrode layers 206 and the second electrode layers 208 may include one or more electrically conductive materials, such as molybdenum (Mo), chromium (Cr), titanium nitride (TiN), tantalum nitride (TaN), titanium (Ti). aluminum (Al), gold (Au), silver (Ag), cobalt (Co), copper (Cu), ruthenium (Ru), platinum (Pt), and/or another suitable electrically conductive material. The insulator layers 210 may include one or more low-k dielectric materials, one or more high-k dielectric materials, and/or another type of electrically insulating material. Examples include zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layers 210 each include a multiple-layer stack that includes a plurality of dielectric layers. For example, an insulator layer 210 may include a ZrO₂/Al₂O₃/ZrO₂ (ZAZ) layer stack.

As further shown in FIG. 2A, the first electrode layers 206, the second electrode layers 208, and the insulator layers 210 may extend above the trench 202 and laterally outward from the trench. The portions of the first electrode layers 206 that extend laterally outward from the trench 202 along the surface of the layer 204 may be electrically connected and/or physically connected to one or more first contact structures 214 (e.g., CBM contacts). The portions of the second electrode layers 208 that extend laterally outward from the trench 202 along the surface of the layer 204 may be electrically connected and/or physically connected to one or more second contact structures 216 (e.g., CTM contacts). The first contact structures 214 and/or the second contact structures 216 may correspond to conductive structures 142, conductive structures 160, conductive structures 172, and/or other conductive structures in the semiconductor die package 100.

FIG. 2B illustrates another example capacitor structure 218. As shown in FIG. 2B, the capacitor structure 218 includes a first electrode layer 206, a second electrode layer 208, and an insulator layer 210 between the first electrode layer 206 and the second electrode layer 208. The first electrode layer 206, the second electrode layer 208, and the insulator layer 210 may be arranged as a planar thin-film stack in the layer 204. Thus, the capacitor structure 218 may be referred to as a planar capacitor, a parallel plate capacitor, and/or a thin-film capacitor, among other examples.

The capacitor structure 218 may further include one or more capping layers that facilitate etching of the first electrode layer 206, the second electrode layer 208, and/or the insulator layer 210, and/or that may provide electrical isolation for the capacitor structure 218. For example, the capacitor structure 218 may include a capping layer 220 on the second electrode layer 208. In some implementations, the capping layer 220 is used as a hard mask to pattern and define the second electrode layer 208. As another example, the capacitor structure 218 may include a capping layer 222 and a capping layer 224. Portions of the capping layers 222 and 224 may be included above the insulator layer 210 and portions of the capping layers 222 and 224 may be included above the capping layer 220.

The first contact structure 214 may land on the first electrode layer 206, and may extend through the insulator layer 210 and the capping layers 222 and 224. The second contact structure 216 may land on the second electrode layer 208 and may extend through the capping layers 222-224.

As indicated above, FIGS. 2A and 2B are provided as examples. Other examples may differ from what is described with regard to FIGS. 2A and 2B.

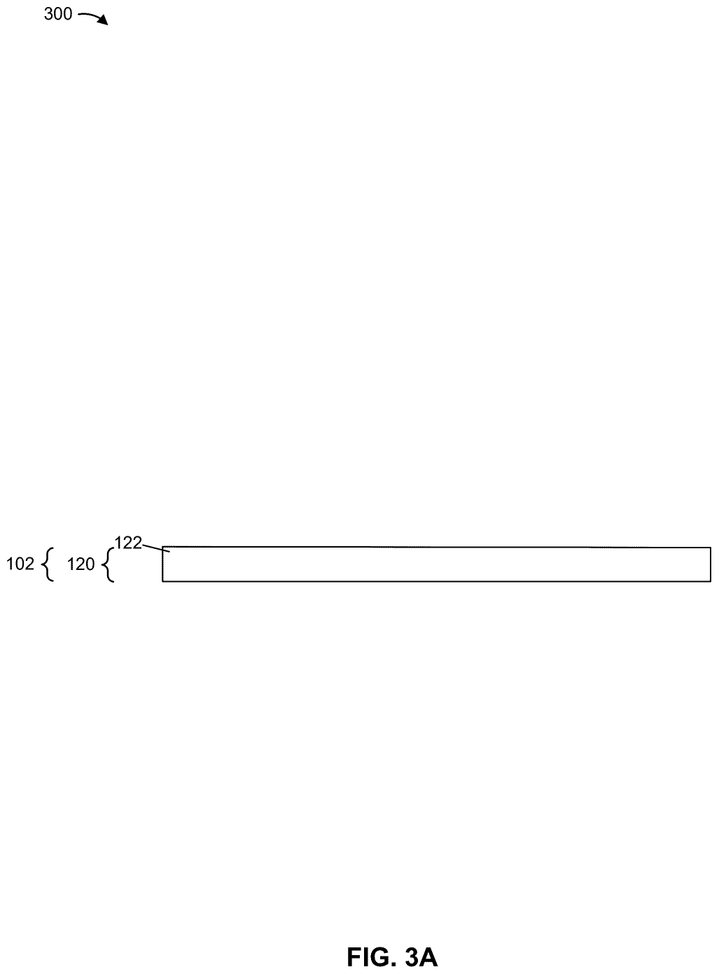

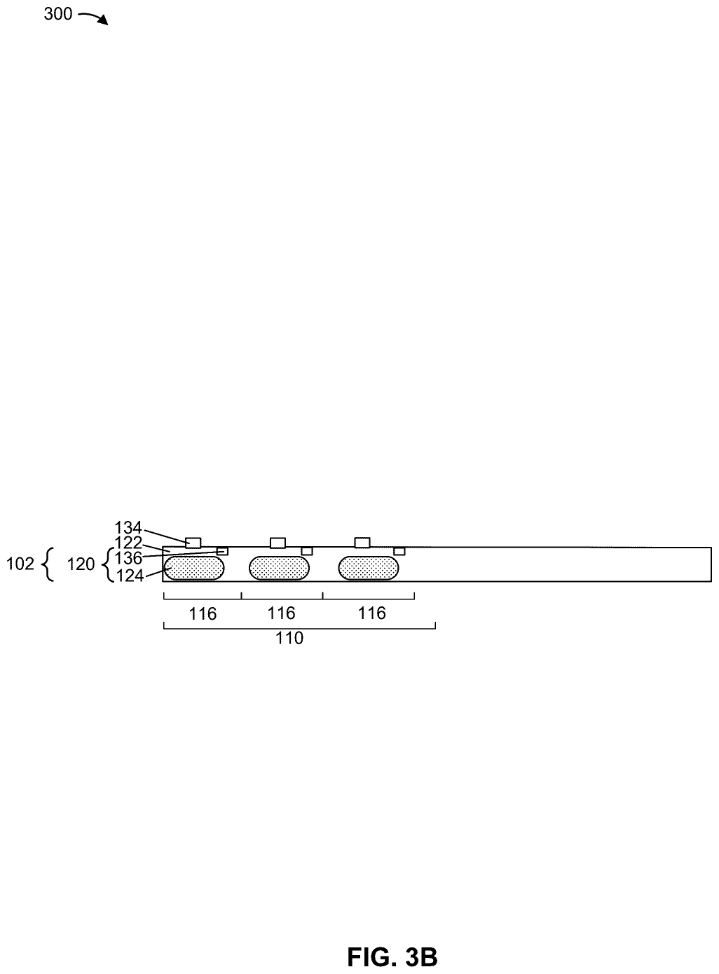

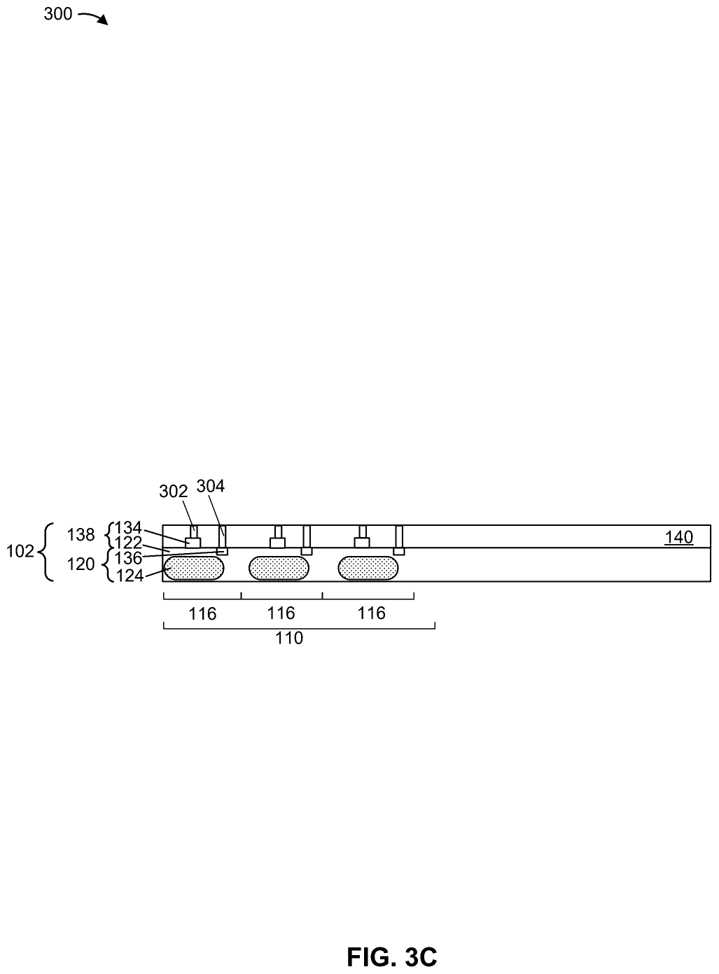

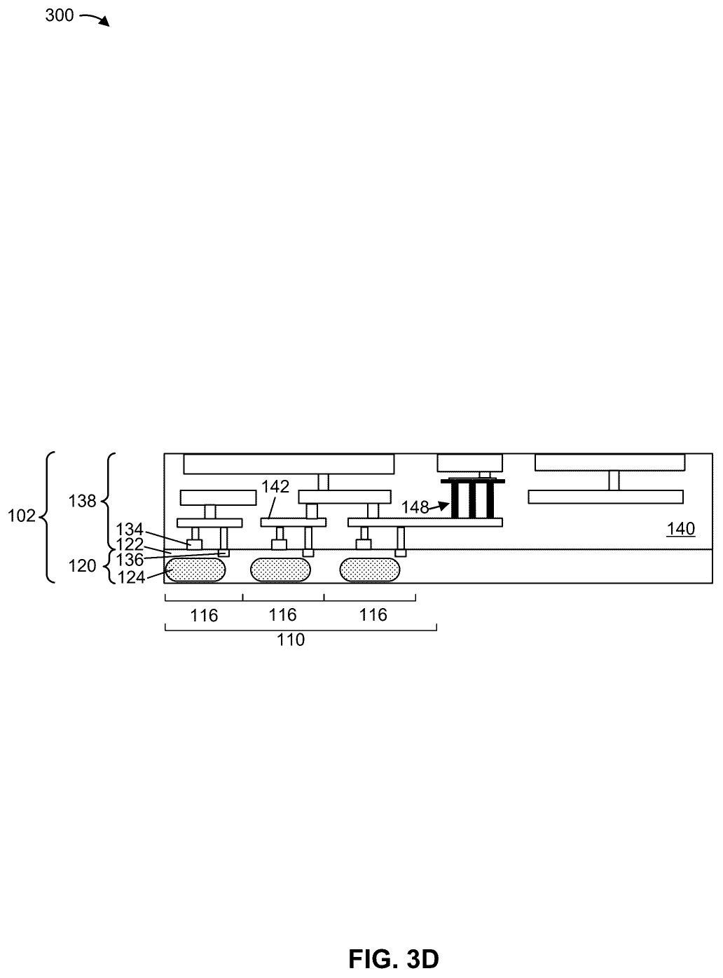

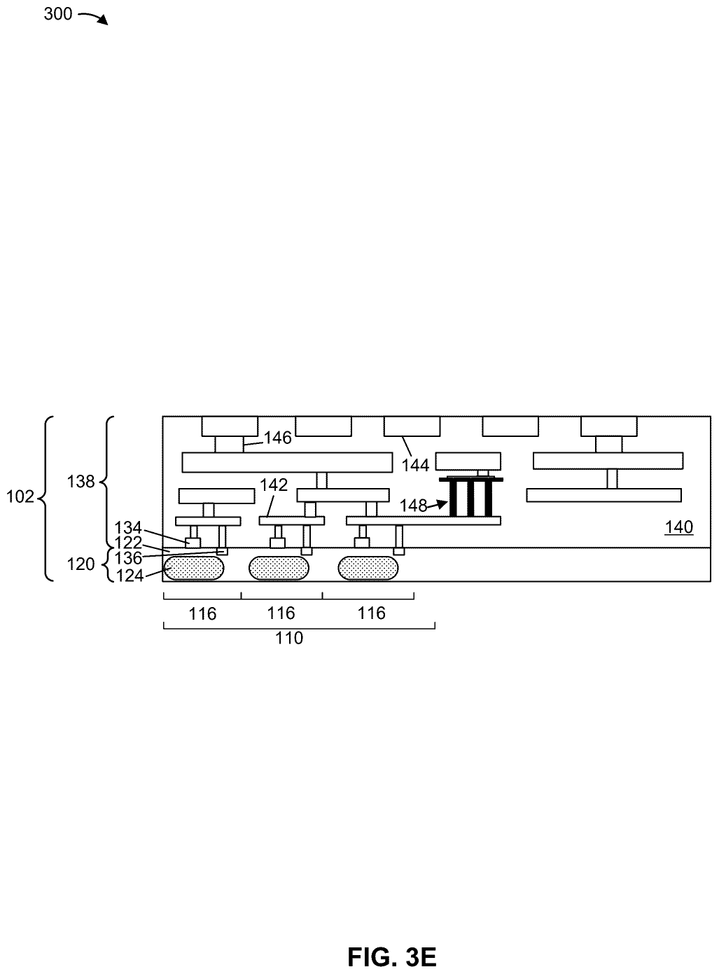

FIGS. 3A-3E are diagrams of an example implementation 300 of forming the semiconductor die 102 (or a portion thereof) described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 3A, the substrate layer 122 of the device layer 120 of the semiconductor die 102 is provided. The substrate layer 122 may be provided in the form of a semiconductor wafer such as a silicon (Si) wafer may be provided as an SOI wafer, and/or another type of semiconductor work piece.

As shown in FIG. 3B, photodiodes 124 of pixel sensors 116 of a pixel sensor array 110 of the semiconductor die 102 may be formed in the substrate layer 122 from the frontside of the substrate layer 122. In some implementations, an ion implantation tool may be used to implant ions into the substrate layer 122 to form a P-N junction between a p-doped region of the substrate layer 122 and an n-doped region of the substrate layer 122, or to form a P-I-N junction between p-doped region of the substrate layer 122, an n-doped region of the substrate layer 122, and an intrinsic (e.g., undoped) semiconductor region for a photodiode 124.

As further shown in FIG. 3B, additional regions of the substrate layer 122 may be doped to form the floating diffusion nodes 136. Transfer gates 134 of the pixel sensors 116 may be formed over and/or on the frontside surface of the substrate layer 122. Forming a transfer gates 134 may include deposing a gate dielectric on the front side surface of the substrate layer 122, depositing a gate electrode on the gate dielectric layer, and/or forming sidewall spacers on sidewalls of the gate electrode, among other examples.

As in FIG. 3C, a portion of the dielectric region 140 of the interconnect layer 138 of the semiconductor die 102 may be formed over the frontside of the substrate layer 122. A deposition tool may be used to deposit the portion of the dielectric region 140 using a physical vapor deposition (PVD) technique, an atomic layer deposition (ALD) technique, a chemical vapor deposition (CVD) technique, an oxidation technique, and/or another suitable deposition technique. The portion of the dielectric region 140 may be deposited in one or more deposition operations. In some implementations, a planarization tool may be used to perform a planarization operation (e.g., a chemical mechanical planarization (CMP) operation) to planarize the portion of the dielectric region 140 after the portion of the dielectric region 140 is deposited.

Gate contacts 302 and source/drain contacts 304 may be formed in the dielectric region 140. For example, the gate contacts 302 may be formed on the transfer gates 134 of the pixel sensors 116, and the source/drain contacts 304 may be formed on the floating diffusion nodes 136 of the pixel sensors 116. To form the gate contacts 302 and the source/drain contacts 304, recesses may be formed in the dielectric region 140, and the gate contacts 302 and the source/drain contacts 304 may be formed in the recesses in the dielectric region 140. A deposition tool may be used to deposit the gate contacts 302 and the source/drain contacts 304 using a CVD technique, a PVD technique, an ALD technique, an electroplating technique, and/or another suitable deposition technique. The gate contacts 302 and the source/drain contacts 304 may be deposited in one or more deposition operations. In some implementations, a seed layer is first deposited, and the gate contacts 302 and the source/drain contacts 304 are deposited on the seed layer. In some implementations, one or more liners (e.g., adhesion liners, barrier liners, diffusion liners) are deposited, and then the gate contacts 302 and the source/drain contacts 304 are deposited on the liners. In some implementations, a planarization tool is used to perform a planarization operation (e.g., a CMP operation) to planarize the gate contacts 302 and the source/drain contacts 304 after the gate contacts 302 and the source/drain contacts 304 are deposited.

As shown in FIG. 3D, additional portions of the interconnect layer 138 of the semiconductor die 102 may be formed above the frontside of the substrate layer 122. One or more semiconductor processing tools may be used to form the interconnect layer 138 by forming one or more dielectric layers of the dielectric region 140 and forming a plurality of conductive structures 142 in the dielectric layer(s) of the dielectric region 140. For example, a deposition tool may be used to deposit a first dielectric layer of the dielectric region 140 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 142 in the recesses (e.g., using a CVD technique, an ALD technique, a PVD technique, an electroplating technique, and/or another type of deposition technique). At least a portion of the first layer of conductive structures 142 may be electrically connected and/or physically connected with the transfer gates 134 and/or with the floating diffusion nodes 136 (e.g., directly connected or connected through contacts 302 and/or 304). Similar processing operations may be performed to form additional layers of the interconnect layer 138 until a sufficient or desired arrangement of conductive structures 142 is achieved.

As further shown in FIG. 3D, one or more capacitor structures 148 may be formed above the frontside of the substrate layer 122 in the interconnect layer 138. For example, a capacitor structure 148 may be formed according to the structural arrangement of the capacitor structure 200 (e.g., a trench capacitor structure) illustrated in FIG. 2A. In these examples, a trench 202 may be formed in the dielectric region 140. One or more first electrode layers 206, one or more second electrode layers 208, and one or more insulator layers 210 may be formed in the trench 202 in an alternating manner. First contact structures 214 may be formed on the first electrode layer(s) 206, and second contact structures 216 may be formed on the second electrode layer(s) 208. As another example, a capacitor structure 148 may be formed according to the structural arrangement of the capacitor structure 218 (e.g., a thin-film capacitor structure) illustrated in FIG. 2B. In these examples, a first electrode layer 206 is formed, an insulator layer 210 is formed on the first electrode layer 206, and a second electrode layer 208 is formed on the insulator layer 210. The capping layers 220-224 may be formed, and the first contact structure 214 and the second contact structure 216 may be respectively formed on the first electrode layer 206 and the second electrode layer 208.

As shown in FIG. 3E, the bonding vias 146 may be formed on one or more conductive structures 142 in the interconnect layer 138, and bonding pads 144 may be formed above and/or on the bonding vias 146.

As indicated above, FIGS. 3A-3E are provided as an example. Other examples may differ from what is described with regard to FIGS. 3A-3E.

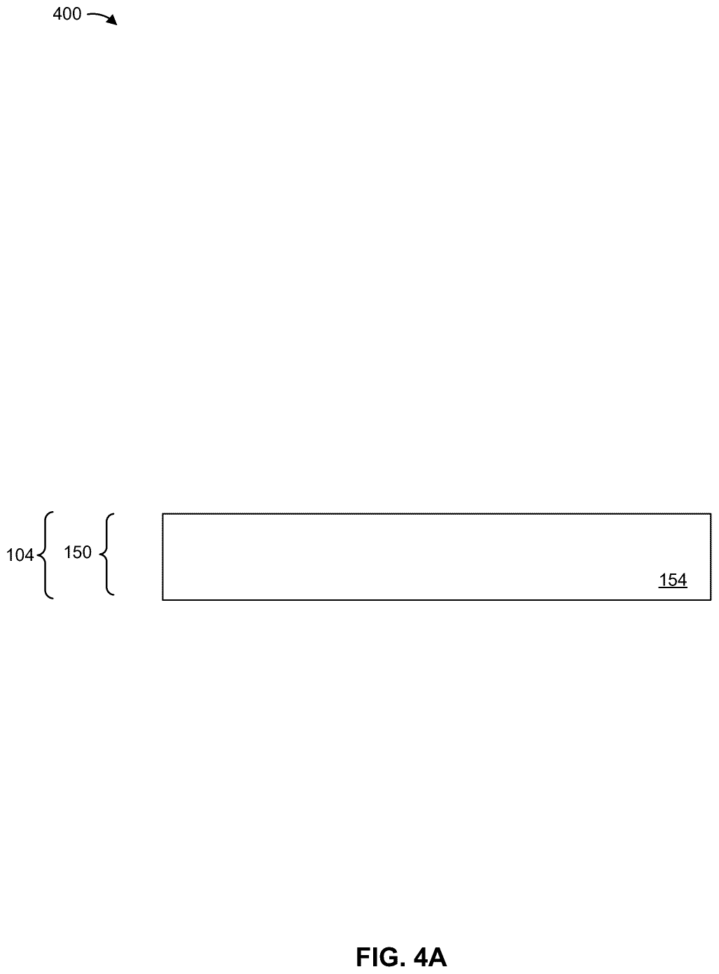

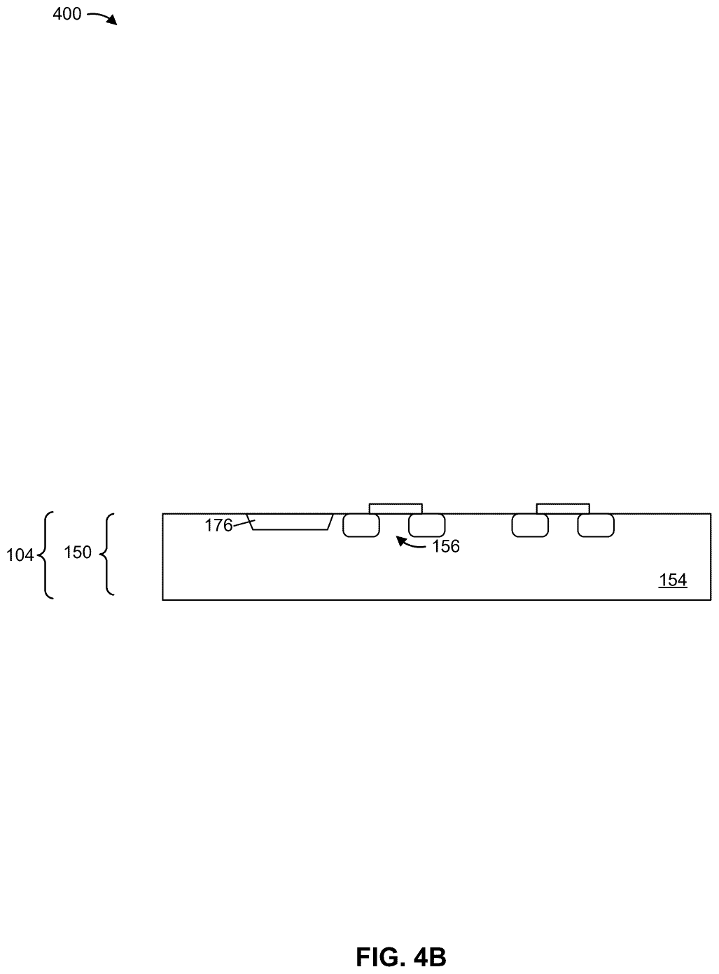

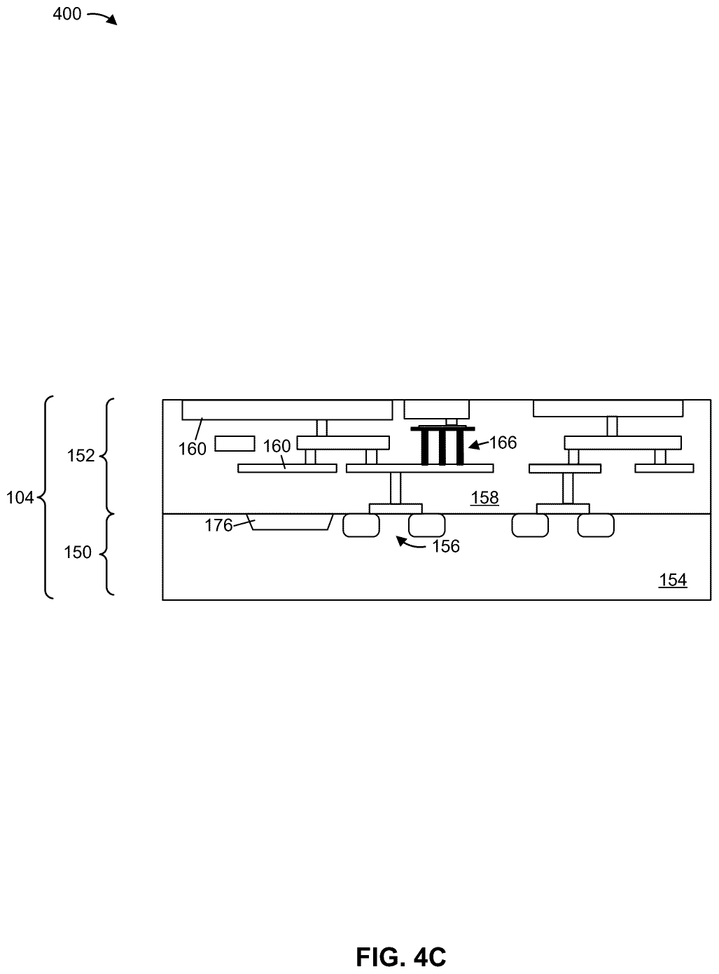

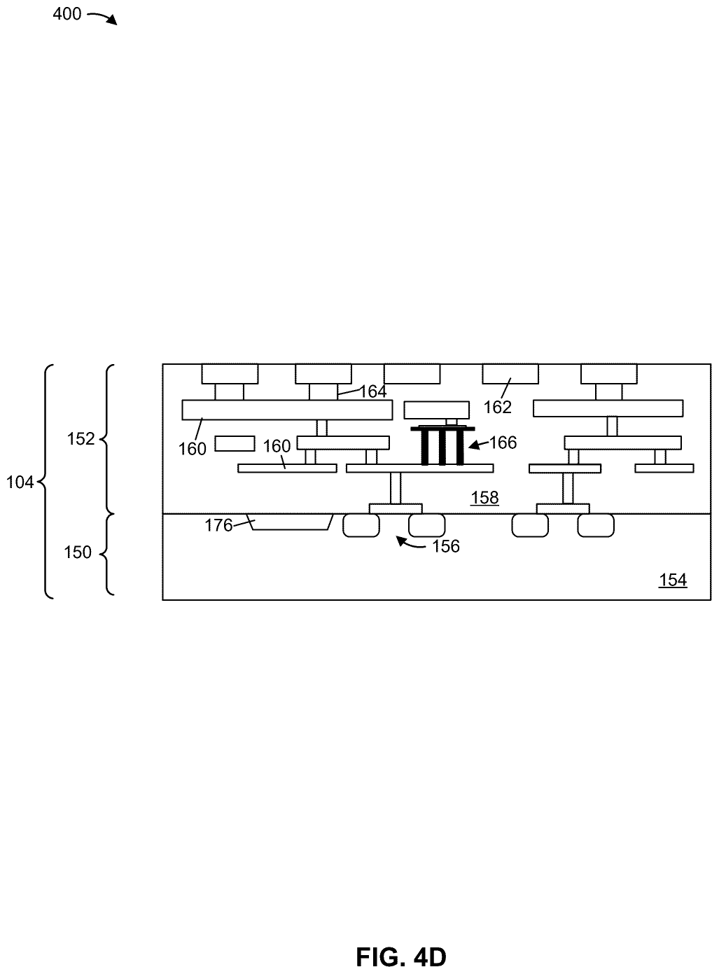

FIGS. 4A-4D are diagrams of an example implementation 400 of forming the semiconductor die 104 (or a portion thereof) described herein. In some implementations, the example implementation 400 includes an example frontside process for the semiconductor die 104. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

Turning to FIG. 4A, one or more of the operations in the example implementation 400 may be performed in connection with the substrate layer 154 of the device layer 150 of the semiconductor die 104. The substrate layer 154 may be provided in the form of a semiconductor wafer (e.g., a silicon wafer), an SOI wafer, or another type of semiconductor substrate.

As shown in FIG. 4B, the integrated circuit devices 156 may be formed in and/or on the frontside of the substrate layer 154 of the device layer 150. One or more semiconductor processing tools may be used to form one or more portions of the integrated circuit devices 156. For example, a deposition tool may be used to perform various deposition operations to deposit layers of the integrated circuit devices 156, and/or to deposit photoresist layers for etching the substrate layer 154 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 154 and/or portions of the deposited layers to form the integrated circuit devices 156. As another example, a planarization tool may be used to planarize portions of the integrated circuit devices 156. As another example, an ion implantation tool may be used to implant ions in the substrate layer 154 to dope portions of the substrate layer 154 with one or more types of dopants (e.g., p-type dopants, n-type dopants).

As further shown in FIG. 4B, an STI region 176 may be formed in frontside of the substrate layer 154. The STI region 176 may be formed in a recess in the substrate layer 154. In some implementations, a pattern in a photoresist layer is used to etch the substrate layer 154 to form the recess in the substrate layer 154. In these implementations, a deposition tool may be used to form the photoresist layer on the substrate layer 154. An exposure tool may be used to expose the photoresist layer to a radiation source to pattern the photoresist layer. A developer tool may be used to develop and remove portions of the photoresist layer to expose the pattern. An etch tool may be used to etch the substrate layer 154 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 154 based on a pattern.

A deposition tool may be used to deposit the dielectric material of the STI region 176 in the recess using a CVD technique, an ALD technique, a PVD technique, an oxidation technique, and/or another suitable deposition technique. The dielectric material of the STI region 176 may be deposited in one or more deposition operations. In some implementations, a planarization tool may be used to perform a planarization operation (e.g., a CMP operation) to planarize the STI region 176 after the dielectric material of the STI region 176 is deposited.

As shown in FIG. 4C, the interconnect layer 152 of the semiconductor die 104 may be formed above the frontside of the substrate layer 154 of the semiconductor die 104. One or more semiconductor processing tools may be used to form the interconnect layer 152 by forming one or more dielectric layers of the dielectric region 158 of the interconnect layer 152 and forming a plurality of conductive structures 160 in the dielectric layer(s) of the dielectric region 158. For example, a deposition tool may be used to deposit a first dielectric layer of the dielectric region 158 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 160 in the recesses (e.g., using a CVD technique, an ALD technique, a PVD technique, an electroplating technique, and/or another type of deposition technique). At least a portion of the first layer of conductive structures 160 may be electrically connected and/or physically connected with the integrated circuit devices 156 in the substrate layer 154 (e.g., directly connected or connected through contacts). Similar processing operations may be performed to form additional layers of the interconnect layer 152 until a sufficient or desired arrangement of conductive structures 160 is achieved.

As further shown in FIG. 4C, one or more capacitor structures 166 may be formed above the frontside of the substrate layer 154 in the interconnect layer 152. For example, a capacitor structure 166 may be formed according to the structural arrangement of the capacitor structure 200 (e.g., a trench capacitor structure) illustrated in FIG. 2A. In these examples, a trench 202 may be formed in the dielectric region 158. One or more first electrode layers 206, one or more second electrode layers 208, and one or more insulator layers 210 may be formed in the trench 202 in an alternating manner. First contact structures 214 may be formed on the first electrode layer(s) 206, and second contact structures 216 may be formed on the second electrode layer(s) 208. As another example, a capacitor structure 166 may be formed according to the structural arrangement of the capacitor structure 218 (e.g., a thin-film capacitor structure) illustrated in FIG. 2B. In these examples, a first electrode layer 206 is formed, an insulator layer 210 is formed on the first electrode layer 206, and a second electrode layer 208 is formed on the insulator layer 210. The capping layers 220-224 may be formed, and the first contact structure 214 and the second contact structure 216 may be respectively formed on the first electrode layer 206 and the second electrode layer 208.

As shown in FIG. 4D, the bonding vias 164 may be formed on one or more conductive structures 160 in the interconnect layer 152, and bonding pads 162 may be formed above and/or on the bonding vias 164.

As indicated above, FIGS. 4A-4D are provided as an example. Other examples may differ from what is described with regard to FIGS. 4A-4D.

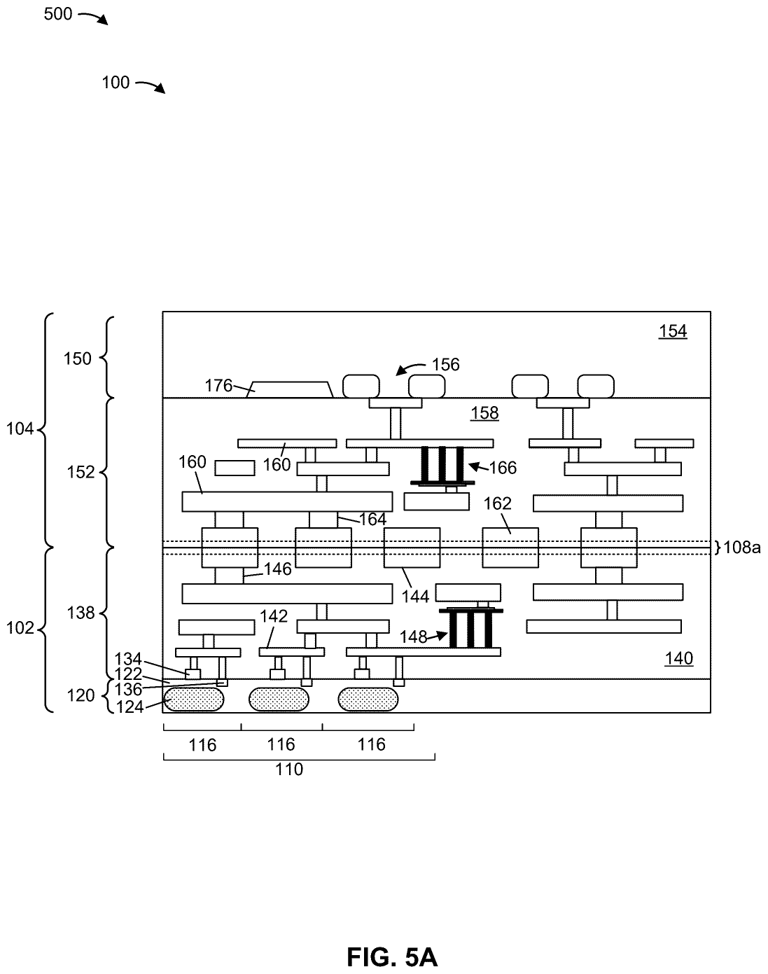

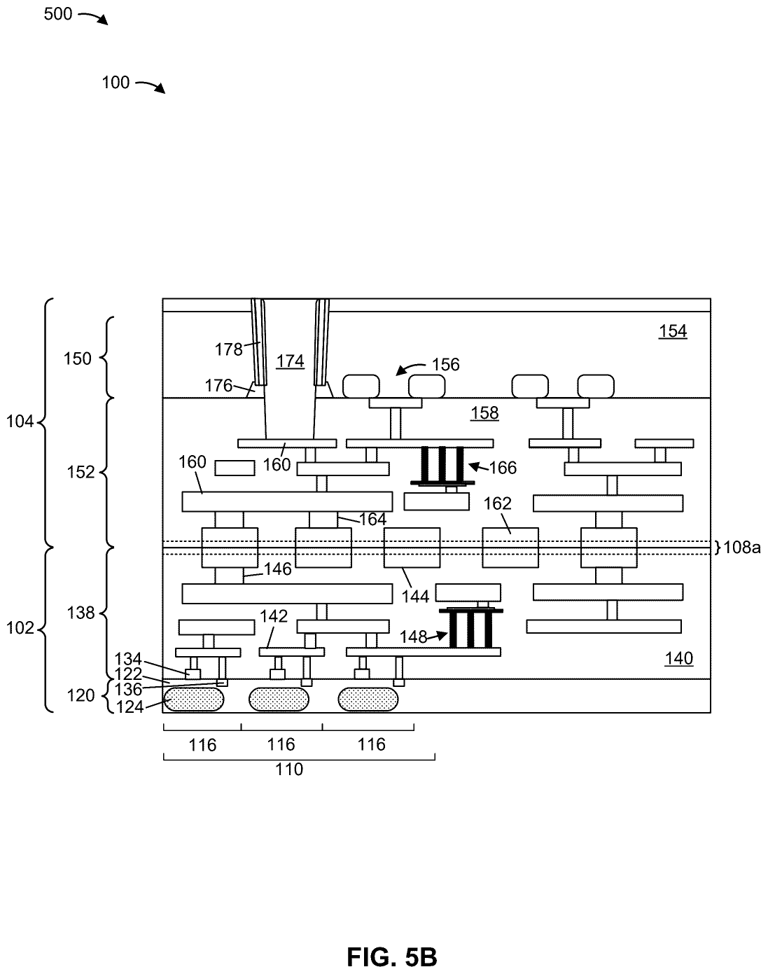

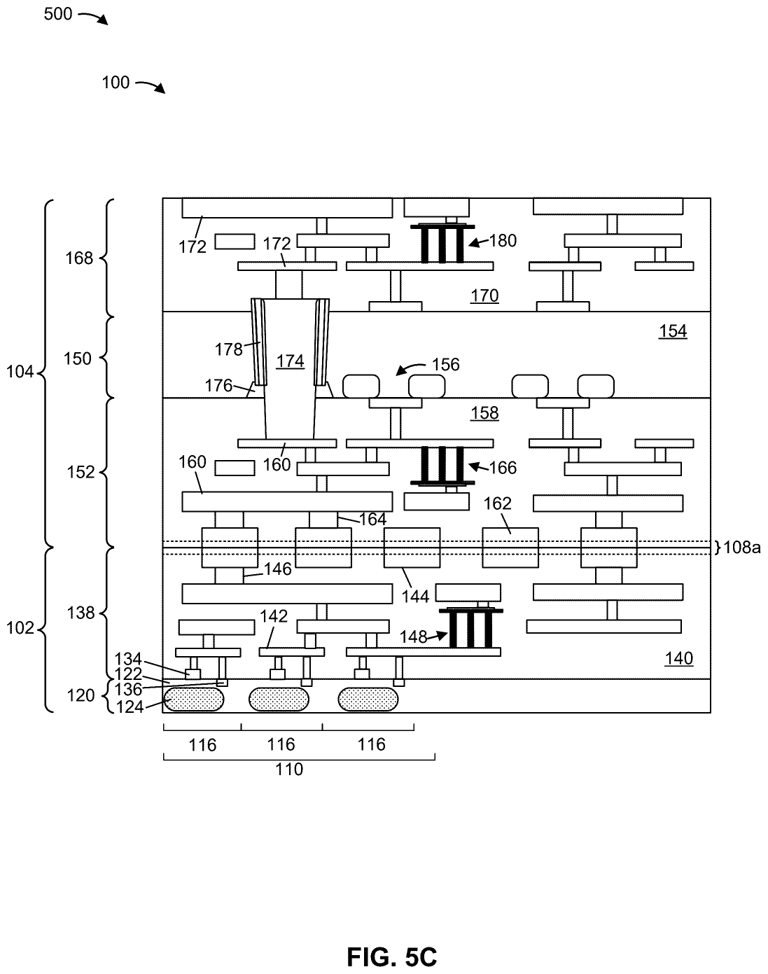

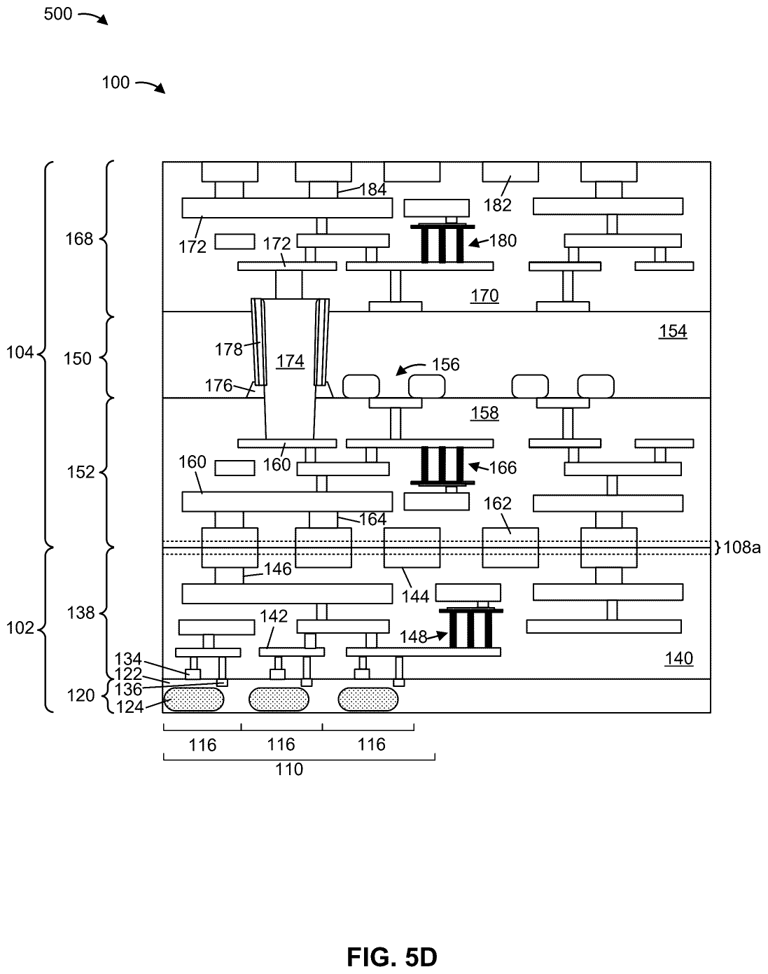

FIGS. 5A-5D are diagrams of an example implementation 500 of forming the semiconductor die package 100 (or a portion thereof) described herein. For example, the example implementation 500 may include an example of bonding the semiconductor dies 102 and 104 of the semiconductor die package 100, and performing backside processing on the semiconductor die 104 after bonding. In some implementations, one or more semiconductor processing tools may be used to perform one or more of the operations described in connection with the example implementation 500, such as a deposition tool, an exposure tool, a developer tool, an etch tool, a planarization tool, a bonding tool, and/or another type of semiconductor processing tool.

As shown in FIG. 5A, a bonding operation is performed to bond the semiconductor die 102 and the semiconductor die 104 at the bonding interface 108a such that the semiconductor die 102 and the semiconductor die 104 are vertically arranged or stacked in the semiconductor die package 100. The semiconductor die 102 and the semiconductor die 104 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 102 and the semiconductor die 104 at the bonding interface 108a. The bonding operation may include forming a direct bond between the semiconductor die 102 and the semiconductor die 104 through a direct physical connection of the bonding pads 144 of the semiconductor die 102 with the bonding pads 162 of the semiconductor die 104, and through a direct physical connection of the dielectric region 140 of the semiconductor die 102 with the dielectric region 158 of the semiconductor die 104. In this way, the interconnect layer 138 on the frontside of the semiconductor die 102 and the interconnect layer 152 on the frontside of the semiconductor die 104 are facing each other in the semiconductor die package 100.

As shown in FIG. 5B, backside processing may be performed on the backside of the semiconductor die 104 after the semiconductor dies 102 and 104 are bonded at the bonding interface 108a. The backside processing may include forming one or more elongated conductive structures 174 (e.g., one or more TSVs) through the substrate layer 154 of the semiconductor die 104 such that the one or more elongated conductive structures 174 land on one or more conductive structures 160 in the interconnect layer 152 on the frontside of the semiconductor die 104.

To form an elongated conductive structure 174, a recess may be formed through the substrate layer 154 from the backside of the substrate layer 154. The recess may extend through the STI region 176 in the substrate layer 154, and into the dielectric region 158 in the interconnect layer 152. A conductive structure 160 in the interconnect layer 152 may be exposed through the recess.

In some implementations, a pattern in a photoresist layer is used to etch the substrate layer 154, the STI region 176, and/or the dielectric region 158 to form the recess. In these implementations, a deposition tool may be used to form the photoresist layer (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate layer 154, the STI region 176, and/or the dielectric region 158 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the material of the elongated conductive structure 174 in the recess using a CVD technique, a PVD technique, an ALD technique, an electroplating technique, and/or another suitable deposition technique. The elongated conductive structure 174 may be deposited in one or more deposition operations. In some implementations, a seed layer is first deposited, and the elongated conductive structure 174 is deposited on the seed layer. In some implementations, one or more liners 178 (e.g., adhesion liners, barrier liners, diffusion liners) are deposited in the recess, and then the elongated conductive structure 174 is deposited on the liners(s) 178. In some implementations, a planarization tool is used to perform a planarization operation (e.g., a CMP operation) to planarize the elongated conductive structure 174 after the elongated conductive structure 174 is deposited.

As shown in FIG. 5C, the interconnect layer 168 of the semiconductor die 104 may be formed above the backside of the substrate layer 154 of the semiconductor die 104. One or more semiconductor processing tools may be used to form the interconnect layer 168 by forming one or more dielectric layers of the dielectric region 170 of the interconnect layer 168 and forming a plurality of conductive structures 172 in the dielectric layer(s) of the dielectric region 170. For example, a deposition tool may be used to deposit a first dielectric layer of the dielectric region 170 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 172 in the recesses (e.g., using a CVD technique, an ALD technique, a PVD technique, an electroplating technique, and/or another type of deposition technique). At least a portion of the first layer of conductive structures 172 may be electrically connected and/or physically connected with the elongated conductive structure 174. Similar processing operations may be performed to form additional layers of the interconnect layer 168 until a sufficient or desired arrangement of conductive structures 172 is achieved.

As further shown in FIG. 5C, one or more capacitor structures 180 may be formed above the backside of the substrate layer 154 in the interconnect layer 168. For example, a capacitor structure 180 may be formed according to the structural arrangement of the capacitor structure 200 (e.g., a trench capacitor structure) illustrated in FIG. 2A. In these examples, a trench 202 may be formed in the dielectric region 170. One or more first electrode layers 206, one or more second electrode layers 208, and one or more insulator layers 210 may be formed in the trench 202 in an alternating manner. First contact structures 214 may be formed on the first electrode layer(s) 206, and second contact structures 216 may be formed on the second electrode layer(s) 208. As another example, a capacitor structure 180 may be formed according to the structural arrangement of the capacitor structure 218 (e.g., a thin-film capacitor structure) illustrated in FIG. 2B. In these examples, a first electrode layer 206 is formed, an insulator layer 210 is formed on the first electrode layer 206, and a second electrode layer 208 is formed on the insulator layer 210. The capping layers 220-224 may be formed, and the first contact structure 214 and the second contact structure 216 may be respectively formed on the first electrode layer 206 and the second electrode layer 208.

As shown in FIG. 5D, the bonding vias 184 may be formed on one or more conductive structures 172 in the interconnect layer 168, and bonding pads 182 may be formed above and/or on the bonding vias 184.

As indicated above, FIGS. 5A-5D are provided as an example. Other examples may differ from what is described with regard to FIGS. 5A-5D.

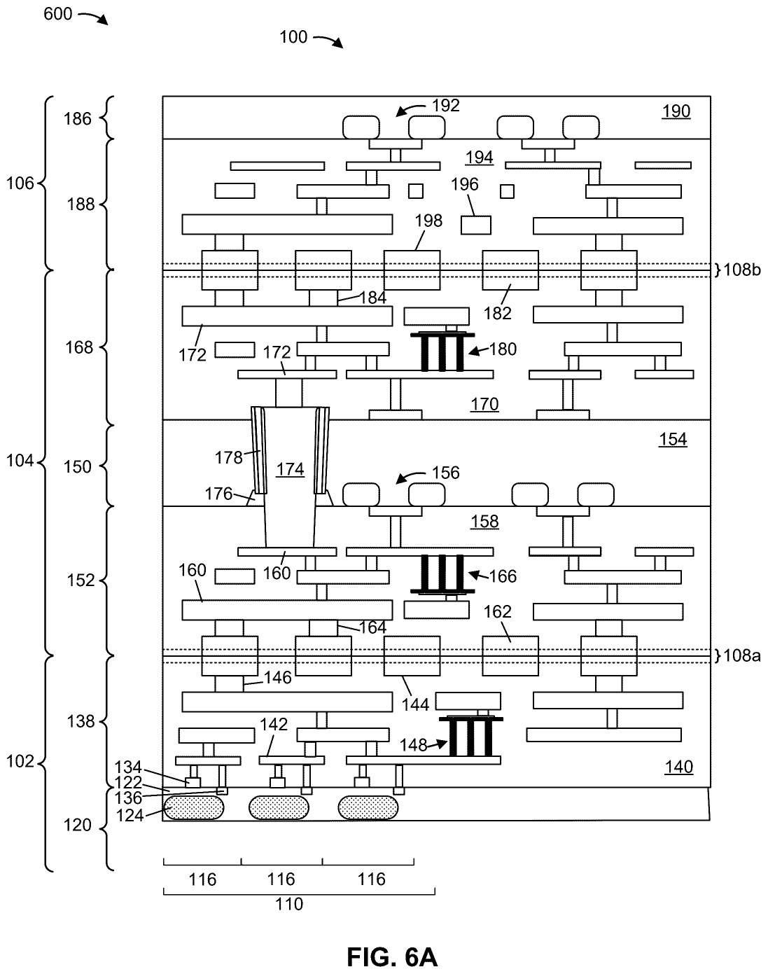

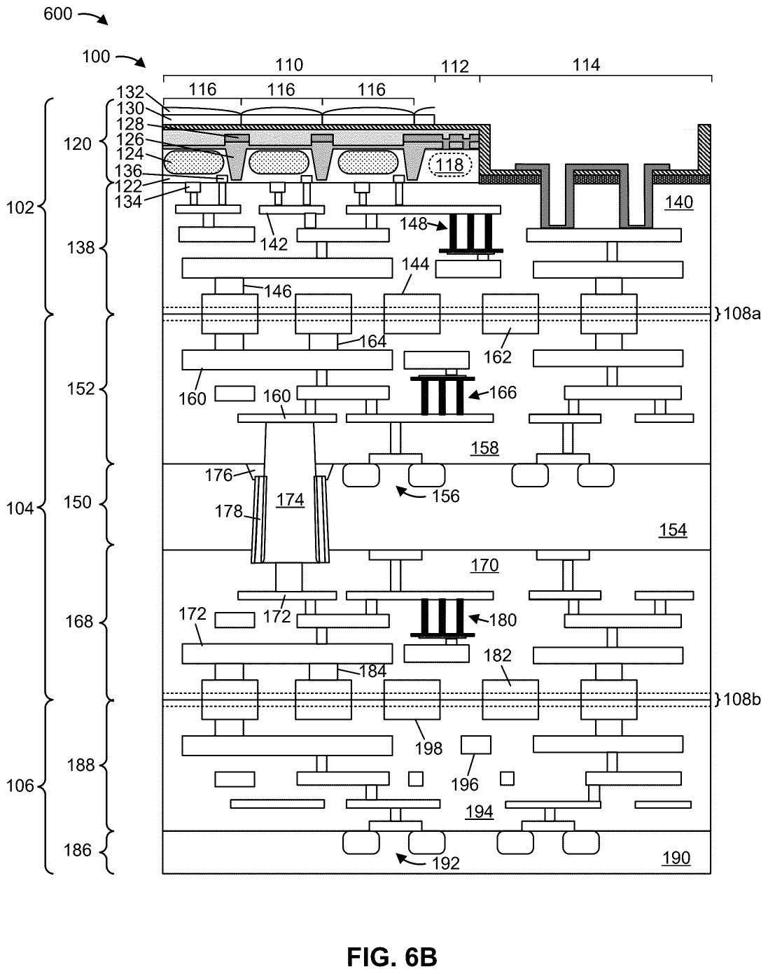

FIGS. 6A and 6B are diagrams of an example implementation 600 of forming the semiconductor die package 100 (or a portion thereof) described herein. For example, the example implementation 600 may include an example of bonding the semiconductor dies 104 and 106 of the semiconductor die package 100, and performing backside processing on the semiconductor die 102 after bonding. In some implementations, one or more semiconductor processing tools may be used to perform one or more of the operations described in connection with the example implementation 600, such as a deposition tool, an exposure tool, a developer tool, an etch tool, a planarization tool, a bonding tool, and/or another type of semiconductor processing tool.

As shown in FIG. 6A, a bonding operation is performed to bond the semiconductor die 104 and the semiconductor die 106 at the bonding interface 108b such that the semiconductor die 104 and the semiconductor die 106 are vertically arranged or stacked in the semiconductor die package 100. The semiconductor die 104 and the semiconductor die 106 may be vertically arranged or stacked in a WoW configuration, a die on wafer configuration, a die on die configuration, and/or another direct bonding configuration. A bonding tool may be used to perform the bonding operation to bond the semiconductor die 104 and the semiconductor die 106 at the bonding interface 108b. The bonding operation may include forming a direct bond between the semiconductor die 104 and the semiconductor die 106 through a direct physical connection of the bonding pads 182 of the semiconductor die 104 with the bonding pads 198 of the semiconductor die 106, and through a direct physical connection of the dielectric region 170 of the semiconductor die 104 with the dielectric region 194 of the semiconductor die 106. In this way, the interconnect layer 168 on the backside of the semiconductor die 104 and the interconnect layer 188 on the frontside of the semiconductor die 106 are facing each other in the semiconductor die package 100.

The semiconductor die 106 may be formed by similar operations and/or using similar techniques as described in connection with FIGS. 4A-4D for the semiconductor die 104.

As shown in FIG. 6B, backside processing may be performed on the backside of the semiconductor die 102 after the semiconductor dies 104 and 106 are bonded at the bonding interface 108b. The backside processing may include additional processing to form the pixel array 110, the BLC region 112, and/or the bonding pad region 114. For example, the DTI structure 126 may be formed in the backside of the substrate layer 122 such that the DTI structure 126 laterally surrounds the photodiodes 124 of the pixel sensors 116. As another example, the grid structure 128 may be formed above the backside of the substrate layer 122, the color filter regions 130 may be above the photodiodes 124 on the backside of the substrate layer 122, and the micro-lenses 132 may be formed above the color filter regions 130. As another example, a metal shielding layer may be formed over the region 118 in the BLC region 112. As another example, a bonding pad structure may be formed in the bonding pad region 114.

As indicated above, FIGS. 6A and 6B are provided as an example. Other examples may differ from what is described with regard to FIGS. 6A and 6B.

FIGS. 7A-7K are diagrams of example implementations of the semiconductor die package 100 described herein. The example implementations illustrated in FIGS. 7A-7K include alternative arrangements to the example implementation illustrated in FIG. 1.

FIG. 7A illustrates an example implementation 700 in which the substrate layer 154 of the semiconductor die 104 includes an SOI substrate. In the example implementation 700, the substrate layer 154 includes a semiconductor layer 702 corresponding to the backside of the substrate layer 154 (e.g., the backside of the SOI substrate), an insulator layer 704 (e.g., a buried oxide (BOX) layer of the SOI substrate), and a semiconductor layer 706 corresponding to the frontside of the substrate layer 154 (e.g., the frontside of the SOI substrate).

The semiconductor layer 702, the insulator layer 704, and the semiconductor layer 706 are stacked and vertically arranged in the semiconductor die 104. The semiconductor layer 702 is vertically adjacent to the interconnect layer 168 at a first side of the semiconductor layer 702, and is vertically adjacent to the insulator layer 704 at a second opposing side of the semiconductor layer 702. The insulator layer 704 is vertically between the semiconductor layer 702 and the semiconductor layer 706. The semiconductor layer 706 is vertically adjacent to the interconnect layer 152 at a first side of the semiconductor layer 706, and is vertically adjacent to the insulator layer 704 at a second opposing side of the semiconductor layer 706.

The semiconductor layer 702 and 706 may each include a semiconductor material such as silicon (Si), silicon doped with one or more types of dopants (e.g., p-type dopants, n-type dopants), germanium (Ge), silicon germanium (SiGe), and/or another type of semiconductor material. The insulator layer 704 may include one or more dielectric materials, such as a silicon oxide material (SiOₓ such as SiO₂), a silicon nitride material (SiₓN_{y} such Si₃N₄), and/or another suitable dielectric material.

The SOI substrate arrangement of the substrate layer 154 in the example implementation 700 may provide increased electrical isolation between the frontside and the backside of the substrate layer 154. Thus, the SOI substrate arrangement of the substrate layer 154 in the example implementation 700 may provide increased electrical isolation between the integrated circuit devices 156 (which may be included in the semiconductor layer 706) and the capacitor structures 180 included in the interconnect layer 168. In particular, the insulator layer 704 may prevent current leakage from the capacitor structures 180 and other devices on the backside of the substrate layer 154 from interfering with the operation of the integrated circuit devices 156 in the semiconductor layer 706.

FIG. 7B illustrates an example implementation 708 of the semiconductor die package 100, which is similar to the example implementation illustrated in FIG. 1. However, the capacitor structure(s) 180 in the interconnect layer 168 of the semiconductor die 104 are omitted in the example implementation 708 of the semiconductor die package 100, and one or more capacitor structures 710 are instead included in the backside of the substrate layer 154 of the semiconductor die 104. Thus, the integrated circuit devices 156 are included in the frontside of the substrate layer 154, and the capacitor structure(s) 710 are included in the backside of the substrate layer 154. The one or more capacitor structures 710 may be structurally implemented as capacitor structure(s) 200, capacitor structure(s) 218, and/or in another structural arrangement.

FIG. 7C illustrates an example implementation 712 of the semiconductor die package 100, which is similar to the example implementation 708 in FIG. 7B. However, in the example implementation 712, the substrate layer 154 of the semiconductor die 104 includes an SOI substrate that includes the semiconductor layer 702, the insulator layer 704, and the semiconductor layer 706. The integrated circuit devices 156 on the frontside of the substrate layer 154 may be included in the semiconductor layer 706, and the capacitor structure(s) 710 included in the backside of the substrate layer 154 may be included in the semiconductor layer 702. Thus, the insulator layer 704 is included vertically between the integrated circuit devices 156 and the capacitor structure(s) 710.

The SOI substrate arrangement of the substrate layer 154 in the example implementation 712 may provide increased electrical isolation between the frontside and the backside of the substrate layer 154. Thus, the SOI substrate arrangement of the substrate layer 154 in the example implementation 712 may provide increased electrical isolation between the integrated circuit devices 156 and the capacitor structure(s) 710 included in the substrate layer 154. In particular, the insulator layer 704 may prevent current leakage from the capacitor structure(s) 710 through the substrate layer 154 from interfering with the operation of the integrated circuit devices 156 in the semiconductor layer 706.

FIG. 7D illustrates an example implementation 714 of the semiconductor die package 100, which is similar to the example implementation illustrated in FIG. 1. However, in the example implementation 714 of the semiconductor die package 100, one or more capacitor structures 710 are included in the backside of the substrate layer 154 of the semiconductor die 104, in addition to the capacitor structure(s) 180 being included in the interconnect layer 168 of the semiconductor die 104. Including both the capacitor structure(s) 180 and the capacitor structure(s) 710 on the backside of the semiconductor die 104 may further increase the capacitor density in the semiconductor die 104, and/or may enable fewer capacitor structures 148 to be included in the semiconductor die 102.

FIG. 7E illustrates an example implementation 716 of the semiconductor die package 100, which is similar to the example implementation 714 in FIG. 7D. However, in the example implementation 716, the substrate layer 154 of the semiconductor die 104 includes an SOI substrate that includes the semiconductor layer 702, the insulator layer 704, and the semiconductor layer 706. The integrated circuit devices 156 on the frontside of the substrate layer 154 may be included in the semiconductor layer 706, and the capacitor structure(s) 710 included in the backside of the substrate layer 154 may be included in the semiconductor layer 702. Thus, the insulator layer 704 is included vertically between the integrated circuit devices 156 and the capacitor structure(s) 710.

The SOI substrate arrangement of the substrate layer 154 in the example implementation 712 may provide increased electrical isolation between the frontside and the backside of the substrate layer 154. Thus, the SOI substrate arrangement of the substrate layer 154 in the example implementation 712 may provide increased electrical isolation between the integrated circuit devices 156 and the capacitor structures 180 and 710 included on and/or above the backside of the substrate layer 154.

FIG. 7F illustrates an example implementation 718 of the semiconductor die package 100, which is similar to the example implementation 708 illustrated in FIG. 7B. However, in the example implementation 718 of the semiconductor die package 100, one or more capacitor structures 720 are included in the frontside of the substrate layer 154 of the semiconductor die 104. Thus, the integrated circuit devices 156 and capacitor structure(s) 720 are included in the frontside of the substrate layer 154, and the capacitor structure(s) 710 are included in the backside of the substrate layer 154. The one or more capacitor structures 720 may be structurally implemented as capacitor structure(s) 200, capacitor structure(s) 218, and/or in another structural arrangement. Including both the capacitor structure(s) 166 and the capacitor structure(s) 720 on the frontside of the semiconductor die 104 may further increase the capacitor density in the semiconductor die 104, and/or may enable fewer capacitor structures 148 to be included in the semiconductor die 102.

FIG. 7G illustrates an example implementation 722 of the semiconductor die package 100, which is similar to the example implementation 718 in FIG. 7F. However, in the example implementation 722, the substrate layer 154 of the semiconductor die 104 includes an SOI substrate that includes the semiconductor layer 702, the insulator layer 704, and the semiconductor layer 706. The integrated circuit devices 156 and the capacitor structure(s) 720 in the frontside of the substrate layer 154 may be included in the semiconductor layer 706, and the capacitor structure(s) 710 included in the backside of the substrate layer 154 may be included in the semiconductor layer 702. Thus, the insulator layer 704 is included vertically between the integrated circuit devices 156 and the capacitor structure(s) 710, and vertically between the capacitor structure(s) 710 and the capacitor structure(s) 720.

FIG. 7H illustrates an example implementation 724 of the semiconductor die package 100, which is similar to the example implementation 718 illustrated in FIG. 7F. However, in the example implementation 714 of the semiconductor die package 100, one or more capacitor structures 710 are included in the backside of the substrate layer 154 of the semiconductor die 104, in addition to the capacitor structure(s) 180 being included in the interconnect layer 168 of the semiconductor die 104. Including the capacitor structure(s) 180 and the capacitor structure(s) 710 on the backside of the semiconductor die 104, and including the capacitor structure(s) 166 and the capacitor structure(s) 720 on the frontside of the semiconductor die 104, may further increase the capacitor density in the semiconductor die 104 and/or may enable fewer capacitor structures 148 to be included in the semiconductor die 102.

FIG. 7I illustrates an example implementation 726 of the semiconductor die package 100, which is similar to the example implementation 724 in FIG. 7H. However, in the example implementation 726, the substrate layer 154 of the semiconductor die 104 includes an SOI substrate that includes the semiconductor layer 702, the insulator layer 704, and the semiconductor layer 706. The integrated circuit devices 156 and the capacitor structure(s) 720 in the frontside of the substrate layer 154 may be included in the semiconductor layer 706, and the capacitor structure(s) 710 included in the backside of the substrate layer 154 may be included in the semiconductor layer 702.

FIG. 7J illustrates an example implementation 728 of the semiconductor die package 100, which is similar to the example implementation illustrated in FIG. 7I. However, in the example implementation 728 of the semiconductor die package 100, one or more capacitor structures 720 are also included in the frontside of the substrate layer 154 of the semiconductor die 104. Thus, the integrated circuit devices 156 and capacitor structure(s) 720 are included in the frontside of the substrate layer 154, and the capacitor structure(s) 180 are included in the interconnect layer 168 above (or below) on backside of the substrate layer 154.

FIG. 7K illustrates an example implementation 730 of the semiconductor die package 100, which is similar to the example implementation 728 in FIG. 7J. However, in the example implementation 730, the substrate layer 154 of the semiconductor die 104 includes an SOI substrate that includes the semiconductor layer 702, the insulator layer 704, and the semiconductor layer 706. The integrated circuit devices 156 and the capacitor structure(s) 720 in the frontside of the substrate layer 154 may be included in the semiconductor layer 706.

As indicated above, FIGS. 7A-7K are provided as an example. Other examples may differ from what is described with regard to FIGS. 7A-7K.

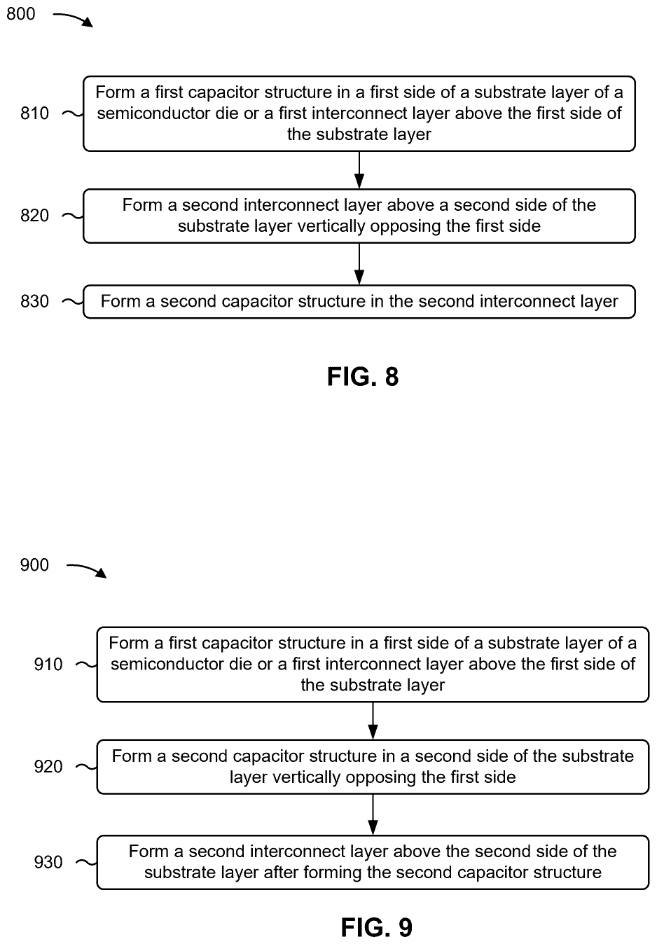

FIG. 8 is a flowchart of an example process 800 associated with forming a semiconductor die package described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming a first capacitor structure in a first side of a substrate layer of a semiconductor die or in a first interconnect layer above the first side of the substrate layer (block 810). For example, one or more semiconductor processing tools may be used to form a first capacitor structure (e.g., a capacitor structure 166, a capacitor structure 720) in a first side of a substrate layer (e.g., a substrate layer 154) of a semiconductor die (e.g., a semiconductor die 104) or in a first interconnect layer (e.g., an interconnect layer 152) above the first side of the substrate layer, as described herein.

As further shown in FIG. 8, process 800 may include forming a second interconnect layer above a second side of the substrate layer vertically opposing the first side (block 820). For example, one or more semiconductor processing tools may be used to form a second interconnect layer (e.g., an interconnect layer 168) above a second side of the substrate layer vertically opposing the first side, as described herein.

As further shown in FIG. 8, process 800 may include forming a second capacitor structure in the second interconnect layer (block 830). For example, one or more semiconductor processing tools may be used to form a second capacitor structure (e.g., a capacitor structure 180) in the second interconnect layer, as described herein.

Process 800 may include additional implementations, such as any single implementation or any combination of implementations described below and/or in connection with one or more other processes described elsewhere herein.

In a first implementation, process 800 includes bonding the first interconnect layer of the semiconductor die to a third interconnect layer (e.g., an interconnect layer 138) of an image sensor die (e.g., a semiconductor die 102) after forming the first capacitor structure in the first interconnect layer.

In a second implementation, alone or in combination with the first implementation, forming the second capacitor structure includes forming the second capacitor structure in the second interconnect layer after bonding the first interconnect layer of the semiconductor die to the third interconnect layer of the image sensor die.

In a third implementation, alone or in combination with one or more of the first and second implementations, process 800 includes bonding the second interconnect layer of the semiconductor die to a fourth interconnect layer (e.g., an interconnect layer 188) of a signal processing die (e.g., a semiconductor die 106) after forming the second capacitor structure in the second interconnect layer.

In a fourth implementation, alone or in combination with one or more of the first through third implementations, process 800 includes forming a third capacitor structure (e.g., a capacitor structure 720) in the first side of the substrate layer prior to forming the first capacitor structure.

In a fifth implementation, alone or in combination with one or more of the first through fourth implementations, process 800 includes forming a third capacitor structure (e.g., a capacitor structure 710) in the second side of the substrate layer after forming the first capacitor structure and prior to forming the second capacitor structure.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

FIG. 9 is a flowchart of an example process 900 associated with forming a semiconductor die package described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming a first capacitor structure in a first side of a substrate layer of a semiconductor die or in a first interconnect layer above the first side of the substrate layer (block 910). For example, one or more semiconductor processing tools may be used to form a first capacitor structure (e.g., a capacitor structure 166, a capacitor structure 720) in a first side of a substrate layer (e.g., a substrate layer 154) of a semiconductor die (e.g., a semiconductor die 104) or in a first interconnect layer (e.g., an interconnect layer 152) above the first side of the substrate layer, as described herein.

As further shown in FIG. 9, process 900 may include forming a second capacitor structure in a second side of the substrate layer vertically opposing the first side (block 920). For example, one or more semiconductor processing tools may be used to form a second capacitor structure (e.g., a capacitor structure 710) in a second side of the substrate layer vertically opposing the first side, as described herein.

As further shown in FIG. 9, process 900 may include forming a second interconnect layer above the second side of the substrate layer after forming the second capacitor structure (block 930). For example, one or more semiconductor processing tools may be used to form a second interconnect layer (e.g., an interconnect layer 168) above the second side of the substrate layer after forming the second capacitor structure, as described herein.

Process 900 may include additional implementations, such as any single implementation or any combination of implementations described below and/or in connection with one or more other processes described elsewhere herein.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, an image sensor device includes capacitor structures in multiple semiconductor dies of the image sensor device. The capacitor structures may be configured to store charge associated with a photocurrent that is generated by pixel sensors in a pixel sensor array of a sensor die of the image sensor device. Capacitor structures may be located on a frontside of the sensor die, on a frontside of an application specific integrated circuit (ASIC) die directly bonded to the sensor die, and on a backside of the ASIC die, among other examples. The capacitor structures included on the backside of the ASIC die may be included in a backside of a semiconductor substrate of the ASIC die, and/or may be included in an interconnect layer vertically adjacent to the semiconductor substrate. Including capacitor structures on the frontside and on the backside of the ASIC die enables more efficient use of the die area of the ASIC die for integration of the capacitor structures, which may enable the density of capacitor structures in the image sensor device to be increased without sacrificing area on the sensor die for the photodiodes of the pixel sensors.

As described in greater detail above, some implementations described herein provide a semiconductor die package. The semiconductor die package includes a first semiconductor die. The first semiconductor die includes a first substrate layer, a first interconnect layer vertically adjacent to a first side of the first substrate layer, a second interconnect layer vertically adjacent to a second side of the first substrate layer opposing the first side, a first capacitor structure in the first interconnect layer, and a second capacitor structure in the second interconnect layer. The semiconductor die package includes a second semiconductor die. The second semiconductor die includes a second substrate layer, a third interconnect layer, vertically adjacent to a first side of the second substrate layer, and a pixel sensor array that includes a plurality of pixel sensors on a second side of the second substrate layer opposing the first side. The first interconnect layer of the first semiconductor die is bonded to the third interconnect layer of the second semiconductor dic.

As described in greater detail above, some implementations described herein provide a semiconductor die package. The semiconductor die package includes a first semiconductor die. The first semiconductor die includes a first substrate layer, a first interconnect layer vertically adjacent to a first side of the first substrate layer, a second interconnect layer vertically adjacent to a second side of the first substrate layer opposing the first side, a first capacitor structure in the first interconnect layer, and a second capacitor structure on the second side of the first substrate layer. The second capacitor structure extends into the first substrate layer from the second side of the first substrate layer. The semiconductor die package includes a second semiconductor die. The second semiconductor die includes a second substrate layer, a third interconnect layer vertically adjacent to a first side of the second substrate layer, and a pixel sensor array that includes a plurality of pixel sensors on a second side of the second substrate layer opposing the first side. The first interconnect layer of the first semiconductor die is bonded to the third interconnect layer of the second semiconductor die.

As described in greater detail above, some implementations described herein provide a method. The method includes forming a first interconnect layer above a first side of a substrate layer of a semiconductor die. The method includes forming a first capacitor structure in the first interconnect layer. The method includes forming a second interconnect layer above a second side of the substrate layer vertically opposing the first side. The method includes forming a second capacitor structure in the second interconnect layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die package, comprising:
a first semiconductor die, comprising:
a first substrate layer;
a first interconnect layer vertically adjacent to a first side of the first substrate layer;
a second interconnect layer vertically adjacent to a second side of the first substrate layer opposing the first side;
a first capacitor structure in the first interconnect layer; and
a second capacitor structure in the second interconnect layer; and
a second semiconductor die, comprising:
a second substrate layer;
a third interconnect layer vertically adjacent to a first side of the second substrate layer; and
a pixel sensor array comprising a plurality of pixel sensors on a second side of the second substrate layer opposing the first side,
wherein the first interconnect layer of the first semiconductor die is bonded to the third interconnect layer of the second semiconductor die.

2. The semiconductor die package of claim 1, further comprising:
a third capacitor structure on the first side of the first substrate layer,
wherein the third capacitor structure extends into the first substrate layer from the first side of the first substrate layer.

3. The semiconductor die package of claim 1, further comprising:
a third capacitor structure on the second side of the first substrate layer,
wherein the third capacitor structure extends into the first substrate layer from the second side of the first substrate layer.

4. The semiconductor die package of claim 1, wherein the first substrate layer comprises a silicon (Si) substrate layer.

5. The semiconductor die package of claim 1, wherein the first substrate layer comprises a silicon on insulator (SOI) substrate that comprises:
a first semiconductor layer vertically adjacent to the first interconnect layer;
a second semiconductor layer vertically adjacent to the second interconnect layer; and
an insulator layer vertically between the first semiconductor layer and the second semiconductor layer.

6. The semiconductor die package of claim 5, further comprising:
a third capacitor structure on the second side of the first substrate layer,
wherein the third capacitor structure extends into the first semiconductor layer from the second side of the first substrate layer.

7. The semiconductor die package of claim 1, further comprising:
a third semiconductor die, comprising:
a third substrate layer; and
a fourth interconnect layer vertically adjacent to the third substrate layer,
wherein the fourth interconnect layer of the third semiconductor die is bonded to the second interconnect layer of the first semiconductor die.

8. A semiconductor die package, comprising:
a first semiconductor die, comprising:
a first substrate layer;
a first interconnect layer vertically adjacent to a first side of the first substrate layer;
a second interconnect layer vertically adjacent to a second side of the first substrate layer opposing the first side;
a first capacitor structure in the first interconnect layer; and
a second capacitor structure on the second side of the first substrate layer,
wherein the second capacitor structure extends into the first substrate layer from the second side of the first substrate layer; and
a second semiconductor die, comprising:
a second substrate layer;
a third interconnect layer vertically adjacent to a first side of the second substrate layer; and
a pixel sensor array comprising a plurality of pixel sensors on a second side of the second substrate layer opposing the first side,
wherein the first interconnect layer of the first semiconductor die is bonded to the third interconnect layer of the second semiconductor die.

9. The semiconductor die package of claim 8, further comprising:
a third capacitor structure in the third interconnect layer of the second semiconductor die.

10. The semiconductor die package of claim 8, further comprising:
a third capacitor structure on the first side of the first substrate layer,
wherein the third capacitor structure extends into the first substrate layer from the first side of the first substrate layer.

11. The semiconductor die package of claim 10, wherein the first substrate layer comprises a silicon on insulator (SOI) substrate that comprises:
a first semiconductor layer vertically adjacent to the first interconnect layer;
a second semiconductor layer vertically adjacent to the second interconnect layer; and
an insulator layer vertically between the first semiconductor layer and the second semiconductor layer,
wherein the third capacitor structure is included in the first semiconductor layer.

12. The semiconductor die package of claim 11, wherein the second capacitor structure is included in the second semiconductor layer.

13. The semiconductor die package of claim 8, further comprising:
a third semiconductor die, comprising:
a third substrate layer; and
a fourth interconnect layer vertically adjacent to the third substrate layer,
wherein the fourth interconnect layer of the third semiconductor die is bonded to the second interconnect layer of the first semiconductor die.

14. The semiconductor die package of claim 8, wherein the first substrate layer comprises a silicon on insulator (SOI) substrate that comprises:
a first semiconductor layer vertically adjacent to the first interconnect layer;
a second semiconductor layer vertically adjacent to the second interconnect layer; and
an insulator layer vertically between the first semiconductor layer and the second semiconductor layer,
wherein the second capacitor structure is included in the second semiconductor layer.

15. A method, comprising:
forming a first interconnect layer above a first side of a substrate layer of a semiconductor die;
forming a first capacitor structure in the first interconnect layer;
forming a second interconnect layer above a second side of the substrate layer vertically opposing the first side; and
forming a second capacitor structure in the second interconnect layer.

16. The method of claim 15, further comprising:
bonding the first interconnect layer of the semiconductor die to a third interconnect layer of an image sensor die after forming the first capacitor structure in the first interconnect layer.

17. The method of claim 16, wherein forming the second capacitor structure comprises:
forming the second capacitor structure in the second interconnect layer after bonding the first interconnect layer of the semiconductor die to the third interconnect layer of the image sensor die.

18. The method of claim 16, further comprising:
bonding the second interconnect layer of the semiconductor die to a fourth interconnect layer of a signal processing die after forming the second capacitor structure in the second interconnect layer.

19. The method of claim 15, further comprising:
forming a third capacitor structure in the first side of the substrate layer prior to forming the first capacitor structure.

20. The method of claim 15, further comprising:
forming a third capacitor structure in the second side of the substrate layer after forming the first capacitor structure and prior to forming the second capacitor structure.
